(19) United States
(12) Patent Application Publication
(10) Pub. No.: US 2015/0060995 A1
(43) Pub. Date: Mar. 5, 2015

(54) NONVOLATILE SEMICONDUCTOR STORAGE DEVICE

(71) Applicant: Kabushiki Kaisha Toshiba, Minato-ku (JP)

(72) Inventors: Wataru SAKAMOTO, Yokkaichi (JP); Ryota Suzuki, Yokkaichi (JP)

(73) Assignee: Kabushiki Kaisha Toshiba, Minato-ku (JP)

(21) Appl. No.: 14/474,665

(22) Filed: Sep. 2, 2014

(30) Foreign Application Priority Data
Sep. 2, 2013 (JP) 2013-181251

(51) Int. Cl. H01L 27/115

(52) U.S. Cl. CPC H01L 27/11575; H01L 27/1157; H01L 27/11573
USPC 257/326

(57) ABSTRACT

Nonvolatile semiconductor storage device provided with first to fourth memory-cell unit each including a first select transistor, a second select transistor series connected to the first select transistor, a third select transistor, and memory-cell transistors series connected between the first and the second select transistors and the third select transistor. The memory-cell transistors have a stack structure including a charge storing layer and a control electrode above the charge storing layer via an insulating film. The first to third select transistors each has a stack structure substantially identical to the aforementioned stack structure. Threshold voltages of the first select transistors in the first and the fourth memory-cell unit and the second transistors in the second and third memory-cell unit differ from the threshold voltages of the second select transistors in the first and the fourth memory-cell unit and the first select transistors in the second and third memory-cell unit.

### CROSS-REFERENCE TO RELATED APPLICATION(S)

This application is based upon and claims the benefit of priority from Japanese Patent Application No. 2013-181251, filed on, Sep. 2, 2013, the entire contents of which are incorporated herein by reference.

### FIELD

Embodiments disclosed herein generally relate to a nonvolatile semiconductor storage device.

### BACKGROUND

Nonvolatile semiconductor storage devices are used in various applications. A nonvolatile semiconductor storage device is typically provided with multiplicity of cell units. A cell unit is typically provided with memory-cell transistors disposed between select transistors.

With advances in miniaturization and integration of semiconductor elements, the cell units need to be highly integrated as well. The select transistors and memory-cell transistors, having a similar configuration, may be formed simultaneously. In a memory-cell transistor, an interelectrode insulating film is typically disposed between the charge storing layer and the control electrode. Thus, the select transistor, employing a similar configuration, has a trench extending through the interelectrode insulating film in order to form the select gate.

### BRIEF DESCRIPTION OF THE DRAWINGS

FIG. 1 pertains to a first embodiment and is one example of a block diagram schematically illustrating the electrical configuration of a nonvolatile semiconductor storage device.

FIG. 2 pertains to the first embodiment and is one example of a plan view schematically illustrating the layout of a memory-cell region in part.

FIG. 3A pertains to the first embodiment and is one example of a vertical cross-sectional view taken along line 3A-3A of FIG. 2 schematically illustrating the memory-cell region in part.

FIG. 3B pertains to the first embodiment and is one example of a vertical cross-sectional view taken along line 3B-3B of FIG. 2 schematically illustrating the memory-cell region in part.

FIG. 4 pertains to the first embodiment and is one example of a flowchart schematically indicating a process flow for controlling the threshold voltage of a select transistor to a target value.

FIG. 5 pertains to the first embodiment and is one example of a chart schematically indicating the threshold voltage distribution of the select transistor.

FIGS. 6, 9, and 12 pertain to the first embodiment and are each one example of a plan view indicating the select transistors in which the threshold voltage is to be controlled.

FIGS. 7, 10, 13, and 14 pertain to the first embodiment and are each one example of a cross sectional view indicating the voltage conditions applied to the relevant components when injecting electrons into the select transistor in which the threshold voltage is to be controlled.

FIGS. 8 and 11 pertain to the first embodiment and are each one example of a cross sectional view indicating the voltage conditions applied to the relevant components when injecting electrons into the select transistor in which the threshold voltage is not to be controlled.

FIGS. 15 to 22 pertain to the first embodiment and are each one example of a cross sectional view indicating the voltage conditions applied to the relevant components when programming the memory-cell transistors.

FIG. 23 pertains to a second embodiment and is one example of a block diagram schematically illustrating the electrical configuration of the nonvolatile semiconductor storage device.

FIG. 24 pertains to the second embodiment and is one example of a plan view schematically illustrating the layout of a memory-cell region in part.

FIG. 25A pertains to the second embodiment and is one example of a vertical cross-sectional side view taken along line 25A-25A of FIG. 24 schematically illustrating the memory-cell region in part.

FIG. 25B pertains to the second embodiment and is one example of a vertical cross-sectional side view taken along line 25B-25B of FIG. 24 schematically illustrating the memory-cell region in part.

FIGS. 26A, 27A, 28A, 29A, 30A, 31A, 32A, 33A, and 34A pertain to the second embodiment and are each one example of a vertical cross-sectional side view schematically illustrating one phase of a manufacturing process flow for obtaining the structure illustrated in FIG. 25A.

FIGS. 26B, 27B, 28B, 29B, 30B, 31B, 32B, 33B, and 34B pertain to the second embodiment and are each one example of a vertical cross-sectional side view schematically illustrating one phase of a manufacturing process flow for obtaining the structure illustrated in FIG. 25B.

FIG. 35 pertains to a third embodiment and is one example of a plan view schematically illustrating the layout of a memory-cell region in part.

FIG. 36A pertains to the third embodiment and is one example of a vertical cross-sectional side view taken along line 36A-36A of FIG. 35 schematically illustrating the memory-cell region in part.

FIG. 36B pertains to the third embodiment and is one example of a vertical cross-sectional side view taken along line 36B-36B of FIG. 35 schematically illustrating the memory-cell region in part.

FIGS. 37, 39, 41, and 43 pertain to the third embodiment and are each one example of a plan view schematically illustrating one phase of a manufacturing process flow.

FIGS. 38, 40, 42, and 44 pertain to the third embodiment and are each one example of a vertical cross-sectional side view schematically illustrating one phase of a manufacturing process flow.

### DESCRIPTION

One embodiment of a nonvolatile semiconductor storage device is provided with a first memory-cell unit, a second memory-cell unit, a third memory-cell unit, and a fourth memory-cell unit each including: a first select transistor, a second select transistor series connected to the first select transistor, a third select transistor, and memory-cell transistors series connected between the first and the second select transistors and the third select transistor, each of the memory-cell transistors having a stack structure including a charge storing layer and a control electrode disposed above the charge storing layer via an insulating film, wherein the first, the second, and the third select transistors each has a stack structure substantially identical to the stack structure of the memory-cell transistors; a control circuit; a first bit line connected to an end portion of the first select transistor in the first memory-cell unit and to an end portion of the first select transistor in the second memory-cell unit; a second bit line connected to an end portion of the first select transistor in the third memory-cell unit and to an end portion of the first select transistor in the fourth memory-cell unit; a first source line connected to an end portion of the third select transistor in the first memory-cell unit and to an end portion of the third select transistor in the fourth memory-cell unit; and a second source line connected to an end portion of the third select transistor in the second memory-cell unit and to an end portion of the third select transistor in the third memory-cell unit; threshold voltages of the first select transistors in the first and the fourth memory-cell unit and the second transistors in the second and third memory-cell unit differ from the threshold voltages of the second select transistors in the first and the fourth memory-cell unit and the first select transistors in the second and third memory-cell unit.

One embodiment of a nonvolatile semiconductor storage device is provided with a first memory-cell unit, a second memory-cell unit, a third memory-cell unit, and a fourth memory-cell unit each including: an element region, a first select transistor formed above the element region, a second select transistor formed above the element region and series connected to the first select transistor, a third select transistor formed above the element region, and memory-cell transistors series connected in a first direction between the first and the second select transistors and the third select transistor, the first, the second, the third, and the fourth memory-cell unit being disposed adjacently in a second direction crossing the first direction; a first bit line connected to an end portion of the first memory-cell unit and to an end portion in the second memory-cell unit; a second bit line connected to an end portion in the third memory-cell unit and to an end portion in the fourth memory-cell unit; a first select gate formed of a single electrode disposed above the element region in the first memory-cell unit and above the element region in the fourth memory-cell unit via a gate insulating film; a first select gate line connected to the first select gate disposed above the element region in the first memory-cell unit and to the first select gate disposed above the element region in the fourth memory-cell unit, and extending above and across the element region in the second memory-cell unit and the third memory-cell unit; a second select gate formed of a single electrode disposed above the element region in the second memory-cell unit and above the third memory-cell unit via a gate insulating film; and a second select gate line connected to the second select gate disposed above the element region in the second memory-cell unit and to the second select gate disposed above the element region in the third memory-cell unit, and extending above and across the element regions in the first and the fourth memory-cell unit.

With reference to the accompanying drawings, embodiments of a nonvolatile semiconductor storage device are described hereinafter through a NAND flash memory device application. In the drawings referred to in the following description, elements that are identical or similar are identified with identical or similar reference symbols. Further, for convenience of explanation, directional terms such as up, down, left, right, high and low, as well as deep and shallow for describing the trenches are used in a relative context with respect to a rear side of the later described semiconductor substrate.

### First Embodiment

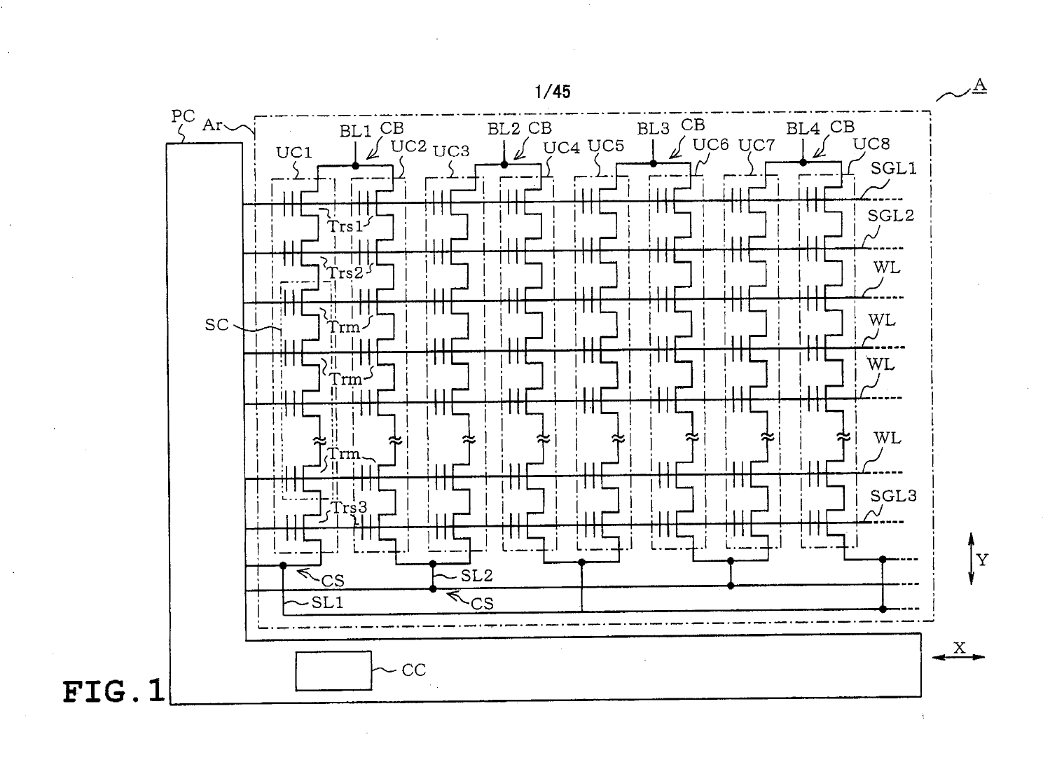

A first embodiment will be described with reference to FIG. 1 to FIG. 14. FIG. 1 is a block diagram schematically illustrating the electrical configuration of a NAND flash memory device.

As illustrated in FIG. 1, flash memory device A is one example of a nonvolatile semiconductor storage device and is provided with memory-cell array Ar and peripheral circuit PC. Memory-cell array Ar is configured by multiplicity of memory cells arranged in a matrix and is driven by peripheral circuit PC.

Peripheral circuit PC is provided with components such a row decoder, a sense amplifier, logic circuitry, control circuitry, and a power supply capacitor (neither illustrated). The row decoder applies stepped-up voltage of word lines WL to the memory cells for each of the blocks in memory-cell array Ar. The sense amplifier is responsible for current detection. Logical circuitry is responsible for processing external signals. The configuration within peripheral circuit PC will not be described in detail for convenience of explanation. Some or all of the components of peripheral circuit PC will be described hereinafter as control circuit CC. Control circuit CC serves as a first pre-processing portion, a second pre-processing portion, and a programming portion.

Memory-cell array Ar includes multiplicity of cell units UC1 to UCn aligned in the X direction. A cell unit is one example of a memory-cell unit and may also be referred to as cell unit UC when referring to an individual cell unit or when referring to cell units in general. Though FIG. 1 only illustrates a single block, multiple blocks are aligned in the Y direction in the actual structure with each block being configured by a cell-unit group containing multiple cell units UC1 to UCn.

Each cell unit UC is provided with three select transistors Trs1, Trs2, and Trs3 and multiple (64 for example) memory-cell transistors Trm. Memory-cell transistors Trm are series connected between select transistors Trs1 and Trs2 and select transistor Trs3. Memory-cell transistors Trm form a cell string SC.

Either of the drain/source of select transistor Trs1 is connected to bit line BL and the remaining other of the drain/source of select transistor Trs1 is connected to either of the drain/source of select transistor Trs2. The remaining other of the drain/source of select transistor Trs2 is connected to one end of cell string SC. The other end of the cell string is connected to either of the drain/source of select transistor Trs3 and the remaining other of the drain/source of select transistor Trs3 is connected to source line SL1 or source line SL2.

As later described, select transistors Trs1, Trs2, and Trs3 are each configured as a stack structure substantially identical to the stack structure of memory-cell transistor Trm.

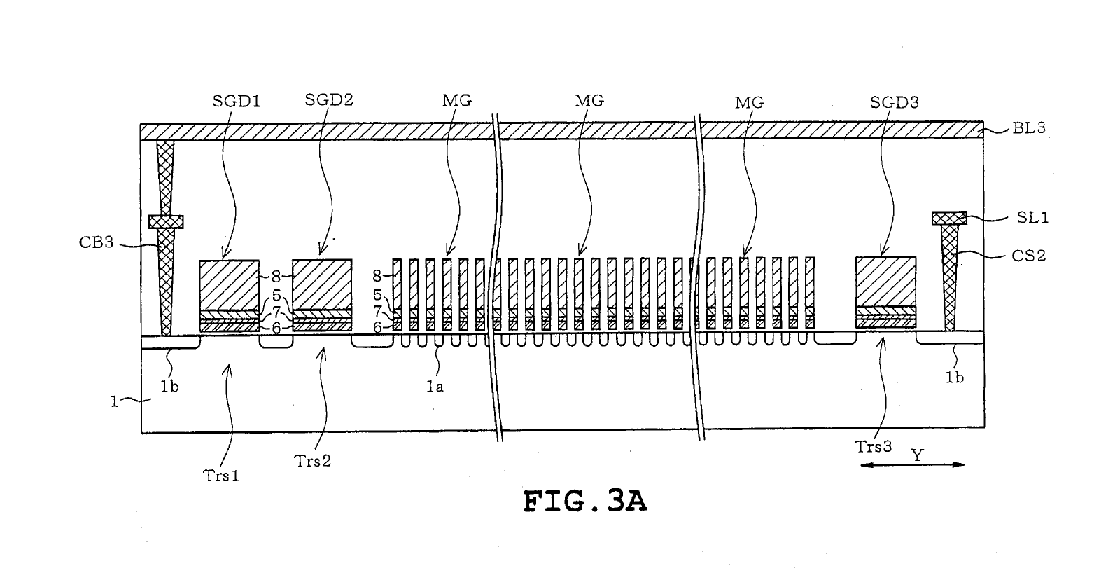

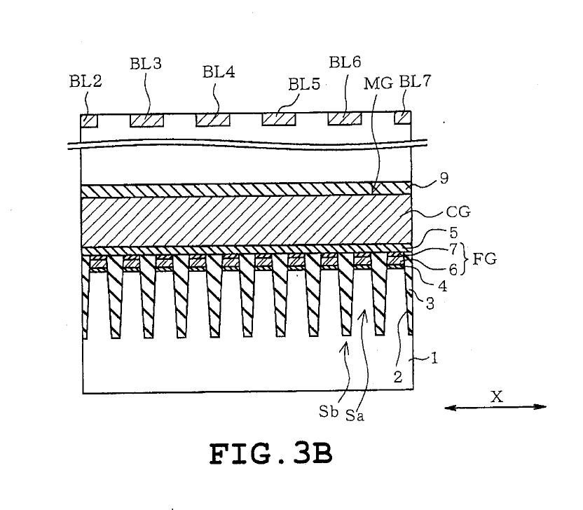

Gates MG (illustrated in FIG. 3B) of memory-cell transistors Trm disposed in multiple cell units UC are interconnected in the X direction by a common word line WL. The X direction may also be referred to a word line direction.

Further, gates SGD1 of select transistors Trs1 (illustrated in FIG. 3A) aligned in the X direction are connected to a common select gate line SGL1 and gates SGD2 of select transistors Trs2 (illustrated in FIG. 3A) are connected to a common select gate line SGL2.

Further, gates SGD3 of select transistors Trs3 (illustrated in FIG. 3A) are connected to a common select gate line SGL3. Bit-line contacts CB (represented as CB1 to CBn/2 in FIG. 3A) are provided in the drain regions of select transistors Trs1. Source-line contacts CS (represented as CS1 to CSn/2 in FIG. 3A) are provided in the drain regions of select transistors Trs3.

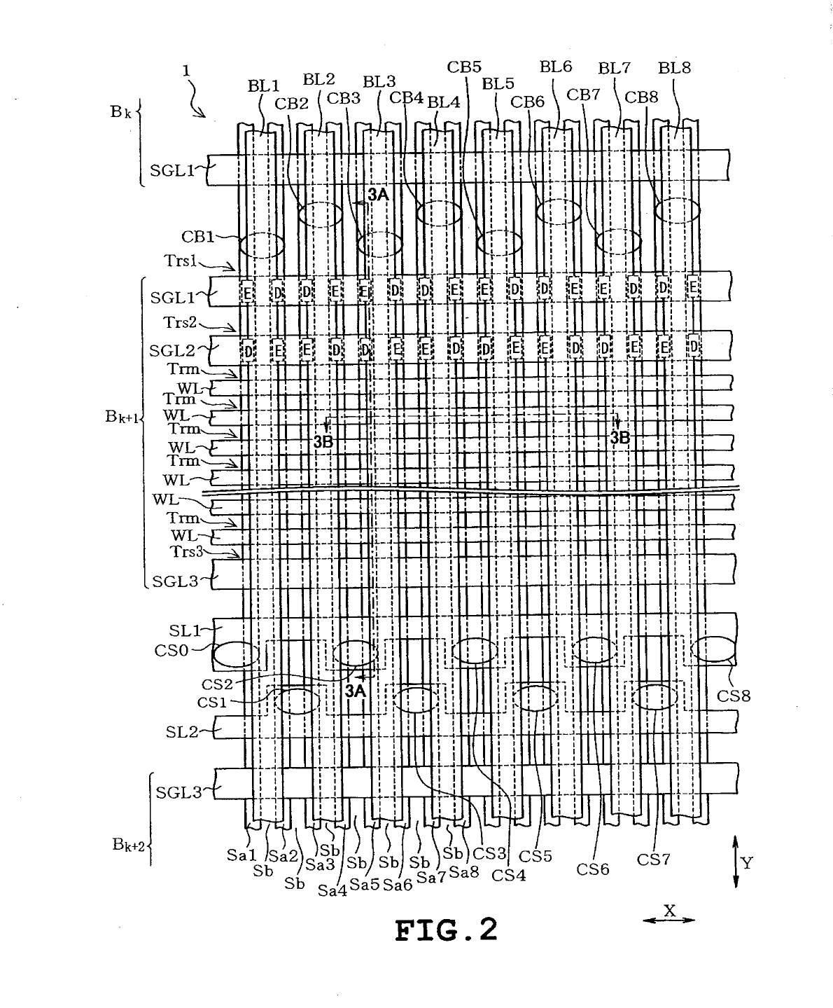

FIG. 2 is one example of a plan view schematically and partially illustrating the layout of a block in the memory-cell region. A description will be given hereinafter on the structure and connection of the wirings of the multiplicity of cell units UC1 to UCn disposed in the X direction within a given block B. Though not identified by reference symbols in FIG. 2, each of cell units UC1 to UCn are disposed in the region where each of element regions Sa1 to San are disposed as viewed planarly.

Each of cell units UC1 to UCn in block Bk (k≧1) is disposed so as to appear to be folded back in the Y direction at the region where each of bit-line contacts CB1 to CBn/2 (hereinafter referred to as bit-line contact CB) is formed so as to be in line symmetry with one another. As illustrated in FIG. 2, select gate line SGL1 of block Bk opposes select gate line SGL1 of block Bk+1 over the region for forming bit-line contact CB.

Similarly, as illustrated in FIG. 2, each of cell units UC1 to UCn in block Bk is disposed so as to appear to be folded back in the Y direction at the region where each of source-line contacts CS0 to CSn/2 (hereinafter referred to as source-line contact CS) is formed so as to be in line symmetry with one another.

As illustrated in FIG. 2, select gate line SGL3 of block Bk+1 opposes select gate line SGL3 of block Bk+2 over the region for forming source-line contact CS.

A silicon substrate for example is used as semiconductor substrate 1. Element isolation regions Sb taking an STI (Shallow Trench Isolation) structure are formed into semiconductor substrate 1 along the Y direction as viewed in FIG. 2. Element isolation regions Sb isolate element regions Sa1 to San of cell units UC1 to UCn in the X direction as viewed in FIG. 2.

Thus, element regions Sa1 to San of cell units UC1 to UCn are isolated from one another by element isolation regions Sb and extend in the Y direction. Element regions Sa1 to San have equal X-direction width and are spaced from one another by equal X-direction distance.

One bit-line contact CBs (s≧1) is formed continuously across and above two element regions Sat−1 and Sat of the odd number cell unit UCt−1 (t≧2s) and the even number cell unit UCt. Bit-line contact CBs is formed for example in the form of an elliptic cylinder.

Stated differently, one bit-line contact CBs is formed continuously across and above two element regions Sat−1 and Sat adjacent in the X direction. One bit line BLs is formed above this bit-line contact CBs. One bit line BLs is formed for every two element regions Sat−1 and Sat to exhibit the so-called shared bit line structure.

Bit lines BLs (s≧1) extend in the Y direction as viewed in FIG. 2 and are spaced from one another in the X direction. Bit lines BLs have equal X direction width and are spaced by equal X direction distance. The X direction width of one bit line BLs is greater than the X direction width of one element region Sa (approximately twice the width of element region Sa for example).

Further, the odd number bit-line contact CBu−1 (u≧2v and v≧1) is disposed so as to be spaced by a first distance from select gate line SGL1 of block Bk+1 and so as to be spaced by a second distance greater than the first distance from select gate line SGL1 of block Bk. In other words, the odd number bit-line contact CBu−1 is disposed relatively closer to select gate line SGL1 of block Bk+1 than to select gate line SGL1 of block Bk.

Further, the even number bit-line contact CBu (u≧2v and v≧1) is disposed so as to be spaced by a third distance from select gate line SGL1 of block Bk and so as to be spaced by a fourth distance greater than the third distance from select gate line SGL1 of block Bk+1. In other words, the even number bit-line contact CBu is disposed relatively closer to select gate line SGL1 of block Bk than to select gate line SGL1 of block Bk+1. As a result, bit-line contact CB1 to CBn/2 are disposed in the so-called zigzag layout.

On the other hand, one source-line contact CSs (s≧0) is formed continuously across and above two element regions Sat and Sat+1 of the even number cell unit UCt (t≧2s) and the odd number cell unit UCt+1. Source-line contact CSs is formed for example in the form of an elliptic cylinder. Stated differently, one source-line contact CSs is formed continuously across and above two element regions Sat and Sat+1 adjacent in the X direction.

Further, the odd number source-line contact CSu−1 (u≧2v and v≧1) is disposed so as to be spaced by a fifth distance from select gate line SGL3 of block Bk+2 and so as to be spaced by a sixth distance greater than the fifth distance from select gate line SGL3 of block Bk+1. In other words, the odd number source-line contact CSu−1 is disposed relatively closer to select gate line SGL3 of block Bk+2 than to select gate line SGL3 of block Bk+1.

Further, the even number source-line contact CSu (u≧2v and v≧1) is disposed so as to be spaced by a seventh distance from select gate line SGL3 of block Bk+1 and so as to be spaced by an eighth distance greater than the seventh distance from select gate line SGL3 of block Bk+2. In other words, the even number source-line contact CSu is disposed relatively closer to select gate line SGL3 of block Bk+1 than to select gate line SGL3 of block Bk+2. As a result, source-line contacts CS are disposed in the so-called zigzag layout.

First source line SL1 is formed above each of even number source-line contact CSu. In the example structure illustrated in FIG. 2, first source line SL1 extends along the X direction so as to be located toward select gate line SGL3 of block Bk+1 with respect to the even number source-line contact CSu.

Further, a portion of first source line SL1 is configured to project in the Y direction as viewed in FIG. 2 and the projection is configured to contact the upper portion of source line contact CSu. Thus, first source line SL1 generally extends in the X direction in a straight line.

Further, second source line SL2 is formed above each of odd number source-line contact CSu−1. As illustrated in FIG. 2, second source line SL2 extends in the X direction so as to be located toward select gate line SGL3 of block Bk+2 with respect to odd number source-line contact CSu−1.

Further, a portion of second source line SL2 is configured to project in the Y direction as viewed in FIG. 2 and the projection is configured to contact the upper portion of source line contact CSu−1. Thus, second source line SL2 generally extends in the X direction in a straight line.

Further, a portion of first source line SL1 is configured to project in the Y direction as viewed in FIG. 2 and the projection is configured to contact the upper portion of source line contact CSu. Thus, first source line SL1 generally extends in the X direction in a straight line.

As described earlier, one bit line BLs is formed for every two element regions Sat−1 and Sat adjacent in the X direction. Bit line BLs is formed for example of copper (Cu). Bit line BLs may be formed of tungsten (W) or aluminum (Al) instead of copper (Cu).

Bit line BLs becomes increasingly influenced by wiring resistance when formed in a narrow width. Thus, in the first embodiment, a shared bit line structure is employed in which one bit line BL is provided for every two element regions Sa as described earlier.

As will be later described, select transistors Trs1, Trs2, and Trs3 are provided with gates SGD1, SGD2, and SGD3, respectively. Each of gates SGD1, SGD2, and SGD3 is provided with the so-called charge storing layer FG. It is possible to control the threshold voltages of select transistors Trs1 to Trs3 based on the amount of charge stored in charge storing layer FG. Control circuit CC of peripheral circuit CC selects either of element regions Sat−1 and Sat when specifying either of cell units UC1 to UCn as a programming cell unit.

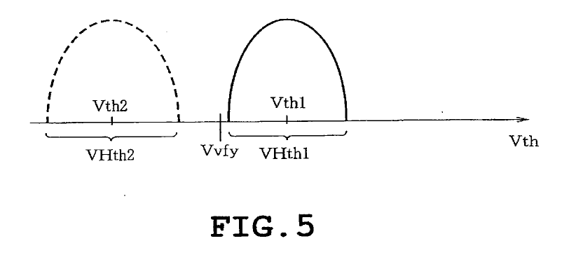

Thus, as illustrated in FIG. 5, select transistors Trs1 and Trs2 are controlled to exhibit threshold voltage Vth1 and threshold voltage Vth2 within different threshold distributions VHth1 and VHth2. Select transistors trs1 and trs2 are categorized into a D type and an E type and are represented as “D” and “E” in FIG. 2. That is, select transistors Trs1 and Trs2 having substantially the same threshold voltages are represented as “D” and “E” in FIG. 2.

In the odd number cell unit UCt−1 and even number cell unit UCt sharing the same bit line BLs, select transistor Trs1 connected to the same select gate line SGL1 is controlled to exhibit a threshold voltage within different threshold voltage distributions VHth1 and VHth2 (as indicated by “D” and “E”).

In the odd number cell unit UCt−1 and even number cell unit UCt sharing the same bit line BLs, select transistor Trs2 connected to the same select gate line SGL2 is controlled to exhibit a threshold voltage within different threshold voltage distributions VHth1 and VHth2 (as indicated by “D” and “E”).

Each of select transistors Trs1 of programming cell units UC (UC1, UC4, UC5, UC8 . . . ) connected to a common first source line SL1 is configured to exhibit threshold voltage Vth1 (represented by “E” in FIG. 2) within first threshold voltage distribution VHth1.

Each of select transistors Trs2 of programming cell units UC(UC1, UC4, UC5, UC8 . . . ) connected to a common first source line SL1 is configured to exhibit threshold voltage Vth2 (represented by “D” in FIG. 2) within second threshold voltage distribution VHth2. Threshold voltage Vth1 within first threshold voltage distribution VHth1 is greater than threshold voltage Vth2 within second threshold voltage distribution VHth2.

Each of select transistors Trs2 of programming cell units UC (UC2, UC3, UC6, UC7 . . . ) connected to a common second source line SL2 is configured to exhibit threshold voltage Vth1 (represented by “E” in FIG. 2) within first threshold voltage distribution VHth1.

Each of select transistors Trs1 of programming cell units UC (UC2, UC3, UC6, UC7 . . . ) connected to a common second source line SL2 is configured to exhibit threshold voltage Vth2 (represented by “E” in FIG. 2) within second threshold voltage distribution VHth2. Further, the threshold voltage of select transistor Trs3 is preset within for example in first threshold voltage distribution VHth1.

The following example is described based on the assumption that every threshold voltage Vth1 within first threshold voltage distribution VHth1 and every threshold voltage Vth2 within second threshold voltage distribution VHth2 satisfy Vth1>0>Vth2 and that the select transistor having the first threshold voltage distribution is an enhancement type transistor and the select transistor having the second threshold voltage distribution is a depletion type transistor. However, it is not required for threshold voltage Vth2 within second threshold voltage distribution VHth2 to take a negative value if the operation voltage is appropriately controlled.

Because the threshold voltages of select transistors Trs1 and Trs2 are preset in an alternate pattern as represented in the zigzag pattern in FIG. 2, either one of cell units UC1 to UCn can be selected, even if bit line BL is shared by a pair of cell units UCt−1 and UCt. It is thus, possible to selectively write data into memory-cell transistors Trm of each memory-cell unit UC1 to UCn.

FIG. 3A schematically illustrates a cross sectional structure of a single cell unit taken along line 3A-3A of FIG. 2. FIG. 3B schematically illustrates a cross sectional structure of a memory-cell region taken along line 3B-3B of FIG. 2.

As described earlier, first and second source lines SL1 and SL2 extend primarily in the X direction and bit line BL extend primarily in the Y direction within memory-cell array Ar. Source lines SL1 and SL2 cross with bit lines BL in plan view. Thus, the wiring layer of source lines SL1 and SL2 and wiring layer of bit lines BL are disposed in different layer levels above semiconductor substrate 1.

As illustrated in FIG. 3A, first source line SL1 is disposed in a wiring layer which is one layer above the layer in which gates MG, SGD1, and SGD2 are formed. Though not illustrated, second source line SL2 may be disposed in the same layer level as first source line SL1. The layer in which gates MG, SGD1, and SGD2 are formed may be disposed in the same layer level as the wiring layer of word lines WL and select gate lines SGL1 and SGL2. The wiring layer of bit lines BL on the other hand, are disposed in the wiring layer above the wiring layer of first and second source lines SL1 and SL2.

Because low level voltage LO (0V for example) is applied to first source line SL1 during the read operation, a dedicated contact CS is not provided for each individual cell unit UC. Instead, first source line SL1 is connected to multiple cell units UC as described earlier. Second source line SL2 is configured in a similar manner.

Referring to FIG. 3A and FIG. 3B, a brief description will be given on the structures of select transistors Trs1, Trs2, and Trs3 as well as memory-cell transistors Trm.

A p-type silicon substrate for example is used as semiconductor substrate 1. Element isolation trenches 2 are formed into semiconductor substrate 1. Element isolation trenches 2 are spaced from one another in the X direction and extend along the Y direction. Element isolation trenches 2 isolate element regions Sa1 to San in the X direction. Element isolation trenches 2 are filled with element isolation films 3. Element isolation region Sb taking an STI (Shallow Trench Isolation) structure is formed in the above described manner.

Tunnel oxide film 4 is formed above element regions Sa1 to San being isolated by element isolation regions Sb. Gate MG is formed above tunnel oxide film 4. Gate MG is formed in the so-called flat gate structure and is provided with charge storing layer FG, IPD (Interpoly dielectric) film 5 serving as an interelectrode insulating film disposed above charge storing layer FG, and control electrode CG disposed above IPD film 5.

Tunnel oxide film 4 is formed above element regions Sa1 to San of semiconductor substrate 1. Tunnel oxide film 4 may be formed of for example a silicon oxide film. The thickness of tunnel oxide film 4 is controlled to range approximately from 5 nm to 8 nm for example. Charge storing layer FG is provided for example with a polysilicon film 6 and charge trap film 7 disposed above polysilicon film 6. Polysilicon film 6 is doped N-type impurities such as phosphorous. Charge trap film 7 may be formed of materials such as a silicon nitride (SiN), hafnium oxide (HfO), or the like. The thickness of silicon film 6 and charge trap film 7 are controlled to approximately 10 nm or less for example.

IPD film 5 is formed above the upper surface of element isolation film 3 and above the upper surface of charge storing layer FG and may also be referred to as an interelectrode insulating film or interconductive layer insulating film. IPD film 5 may be a single layer film formed of a high-dielectric constant film, an oxide film including materials such as nitrogen (N), hafnium (Hf), or aluminum (Al), or a silicon oxide (SiO₂) film. Alternatively, IPD film 5 may be a composite film formed of a combination of the foregoing materials.

Control electrode CG serves as word line WL of memory-cell transistor Trm and is formed of conductive layer 8. Conductive layer 8 is formed of, for example: a metal layer such as a tungsten layer; or a polycrystalline silicon layer doped with impurities such as phosphorous; or a silicide layer; or a composite layer of the foregoing layers.

A barrier metal (not illustrated) is formed between conductive layer 8 and IPD film 5. The barrier metal may be formed of for example, WN, Ti/TiN, or TaN depending upon the materials used in conductive layer 8 and IPD film 5. Above the upper surface of conductive layer 8, insulating film 9 (not illustrated in FIG. 3A) is formed using SiN for example which serves as a cap film.

Further, as illustrated in FIG. 3A, gates MG of memory-cell transistors Trm are aligned in the Y direction. Select gates SGD1 and SGD2 of select transistors Trs1 and Trs2 are disposed on one side of the group of gates MG so as to be spaced from the group of gates MG.

Further, select gate SGD3 of select transistor Trs3 is disposed on the other side of the group of gates MG so as to be spaced from the group of gates MG. Gate isolation trenches (not identified by a reference symbol) are formed between gates MG, between gate MG and gate SGD2, and between gate MG and gate SGD3 to electrically isolate the foregoing gates. The trenches are filled with a silicon oxide film (not illustrated) formed of TEOS (tetraethyl orthosilicate) for example; however, the trenches may be configured as air gaps in order to improve the insulativity between the adjacent gates MG.

The stack structures of select gates SGD1, SGD2, and SGD3 are substantially identical to the stack structure of gate MG of memory-cell transistor Trm and is provided with the so-called charge storing layer FG. Impurity diffusion regions 1a are formed in both sides of gate MG of memory-cell transistor Trm. Further, heavily-doped impurity diffusion regions 1b taking DDD (Double Doped Drain) structure are formed in semiconductor substrate 1 located immediately below bit-line contact CB and source-line contact CS.

In the first embodiment, the stack structures of select gates SGD1, SGD2, and SGD3 are substantially identical to the stack structure of gate MG of memory-cell transistor Trm as described earlier.

However, select gates SGD1, SGD2, and SGD3 of select transistors Trs1, Trs2, and Trs3 differ from gate MG of memory-cell transistor Trm in that the gate length of each of select gates SGD1, SGD2, and SGD3 is greater than the gate length of gate MG.

Further, the distance between select gates SGD1 and SGD2, the distance between select gate SGD2 and gate MG, and the distance between select gate SGD3 and gate MG are configured to be greater than the distance between gates MG of memory-cell transistors Trm.

Interlayer insulating film (not illustrated) is formed above gates MG and select gates SGD1, SGD2, and SGD3. Bit-line contact CB (represented by CB3 in FIG. 3A) and source-line contact CS (represented by CS2 in FIG. 3A) are formed through the interlayer insulating film to establish contact with semiconductor substrate 1.

Bit-line contact CB is disposed beside select gate SGD1 in the Y direction and source-line contact CS is disposed beside select gate SGD3 in the Y direction. Source lines SL1 or SL2 (only source line SL1 is illustrated in FIG. 3A) are formed so as to contact the upper portion of source-line contact CS. Bit line BL (only bit line BL3 is illustrated in FIG. 3A) is formed so as to contact the upper portion of bit-line contact CB.

Three select gate lines SGL (SGL1, SGL2, and SGL3) are provided per block B. This means that the size of block B can be reduced by reducing the number of select gate lines SGL.

Features of the physical structures of the first embodiment are as described above. Threshold voltage Vth of each select transistor Trs1 and Trs2 in each cell unit UC is controlled so that threshold voltage distribution VHth1 and threshold voltage distribution VHth2 differ. A description will be given hereinafter on a method of controlling the threshold voltages of select transistors Trs1 and Trs2.

After forming the above described stack of structures on semiconductor substrate 1 of the semiconductor wafer, the wafer is tested before shipment. For example, the threshold voltages of select transistors Trs1 and Trs2 are controlled so as to fall within first threshold voltage distribution VHth1 or second threshold distribution VHth2 before the test.

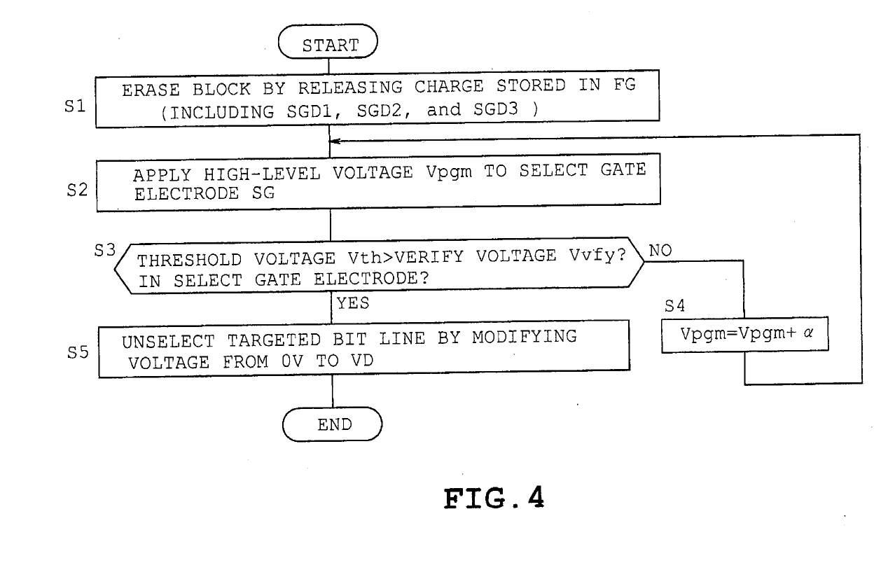

FIG. 4 schematically indicates the step-up programming process for controlling the threshold voltages of select transistors Trs1, Trs2, and Trs3 by way of flowchart. FIG. 5 illustrates the image of how the threshold voltages of select transistors Trs1 to Trs3 are controlled.

First, control circuit CC of peripheral circuit CC applies high level voltage on p well (not illustrated) provided in the surface layer of semiconductor substrate 1. As a result, electrons are ejected to semiconductor substrate 1 side from charge storing layers FG of every memory-cell transistor Trm and select gates SGD2, SGD2, and SGD3 of select transistors Trs1, Trs2, and Trs3 to erase the data stored in the memory cells disposed in block B (step S1 of FIG. 4). As a result, the threshold voltages of all the transistors Trs1, Trs2, Trs3, and Trm within block B are set to threshold voltage Vth2 falling within second threshold voltage distribution VHth2 (threshold voltage Vth2 within second threshold voltage distribution VHth2<threshold voltage Vth1 within first threshold voltage distribution VHth1). In other words, all of the transistors Trs1, Trs2, Trs3, and Trm in block B become type “D”.

Then, control circuit CC of peripheral circuit PC applies high-level voltage Vpgm for programming to the target select gate SG (either of SGD1, SGD2, and SGD3) of select transistor Trs1, Trs2, or Trs3 to increase the threshold voltage (step S2). Thereafter, verification is made as to whether or not threshold voltage Vth has exceeded verify voltage Vvfy (step S3).

If threshold voltage Vth does not exceed verify voltage Vvfy, control circuit CC re-applies high level voltage Vpgm after stepping up programming voltage Vpgm by predetermined voltage α (step S4). Programming voltage Vpgm is gradually increased to the maximum value (20V for example) by repeating steps S2 to S4 to inject electrons into charge storing layer FG.

Then, control circuit CC non-selects the cell unit UC by setting power-supply voltage VD (5V for example) to the bit line BL of the target cell unit UC provided that threshold voltage Vth has exceeded verify voltage Vvfy (step S5).

The threshold voltages of select transistors Trs1, Trs2, and Trs3 are controlled by the process flow indicated in FIG. 4. More specifically, the threshold voltages of select transistors Trs1, Trs2, and Trs3 are preferably controlled individually in the following process flow described in detail.

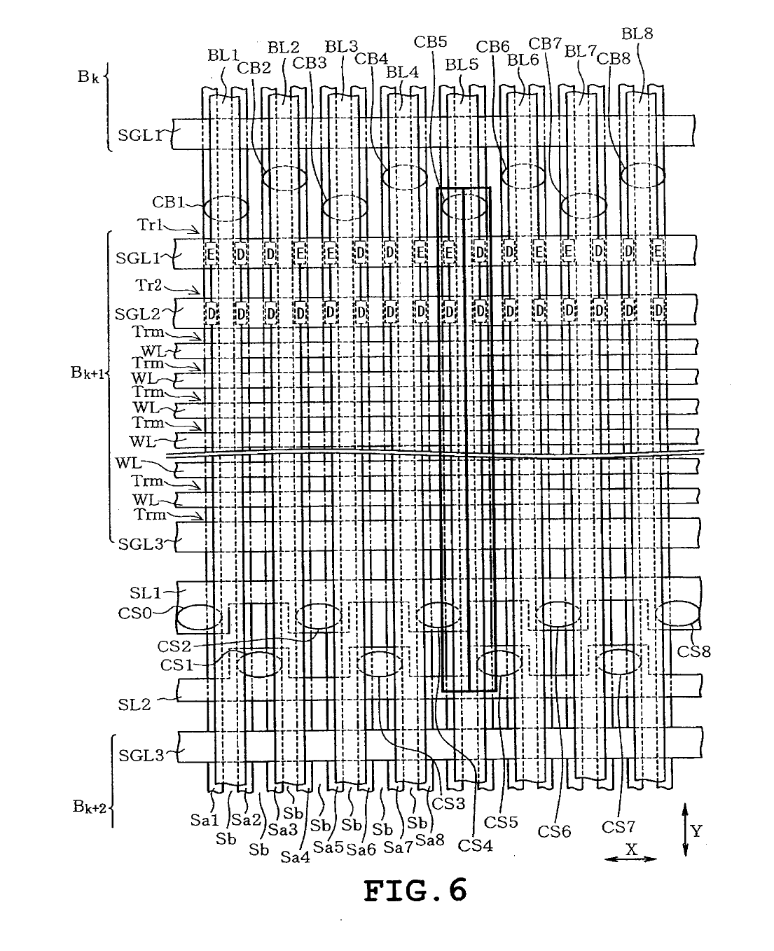

Control circuit CC injects electrons into charge storing layers FG of select gates SGD1 of select transistors Trs1 disposed in cell units UC (UC1, UC4, UC5, UC8 . . . ) connected to a common first source line SL1. As a result, the threshold voltages of select transistors Trs1 disposed in cell units UC (UC1, UC4, UC5, UC8 . . . ) are increased and become type “E” transistors as illustrated in the plan view of FIG. 6.

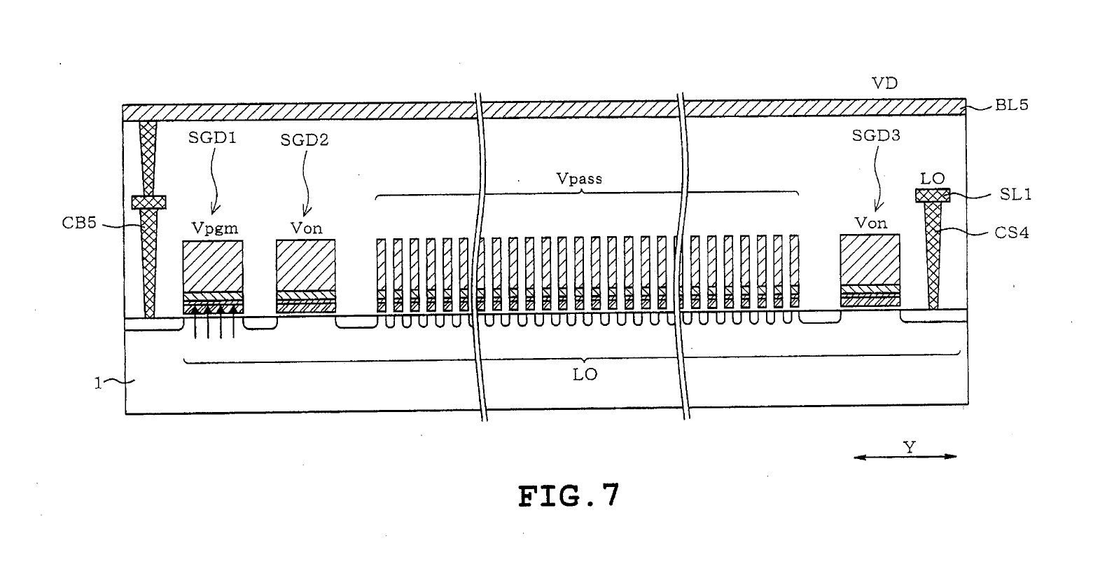

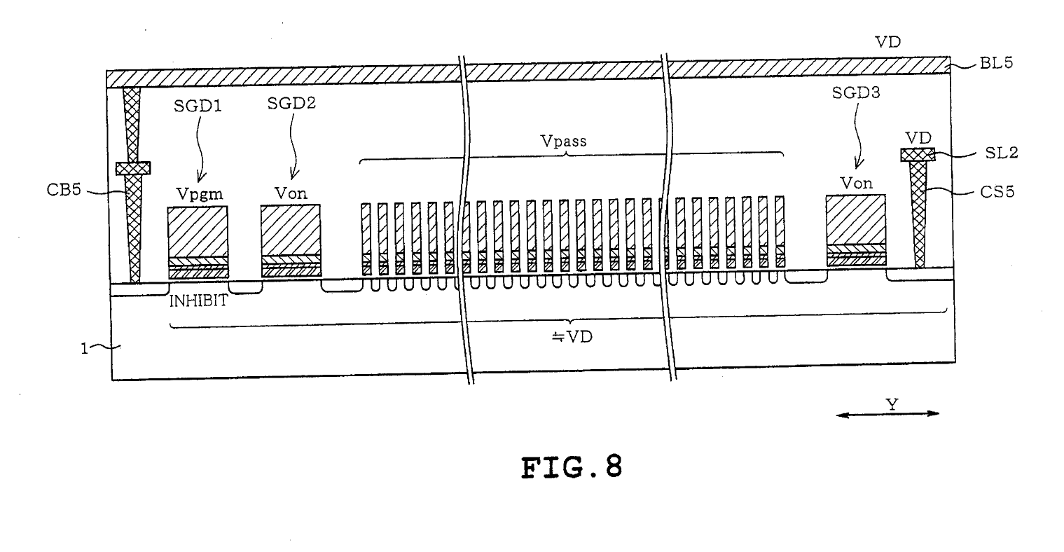

The voltage conditions applied in this control are indicated in FIG. 7 and FIG. 8. FIG. 7 indicates the voltage conditions applied to cell units UC (UC1, UC4, UC5, UC8 . . . ) to be selected. FIG. 8 indicates the voltage conditions applied to cell units UC (UC2, UC3, UC6, UC7 . . . ) to be non-selected. Control circuit CC applies a voltage approximating power-supply voltage VD to all of bit lines BL.

As illustrated in FIG. 7, control circuit CC applies low level voltage LO (0V for example) to first source line SL1, ON control voltage Von to select gate lines SGL2 and SGL3 for effecting the switch to the ON state, and further applies pass voltage Vpass to all of word lines WL (to WL0 to WL63 in case there are 64 word lines).

Thus, low level voltage LO (≈0V) can be applied from first source line SL1 to element regions Sa1, Sa4, Say, Sa8 . . . , by control circuit CC. When high level voltage Vpgm for programming is applied to select gate line SGL1 by the step-up programming process described earlier, it is possible to inject electrons into charge storing layers FG of select gates SGD1 of selected cell units UC (UC1, UC4, UC5, UC8 . . . ).

At this instance, because control circuit CC of peripheral circuit PC applies power-supply voltage VD (≈5V) to second source line SL2 as illustrated in FIG. 8 in cell units UC (UC2, UC3, UC6, UC7 . . . ) to be non-selected, it is possible to apply a voltage approximating power-supply voltage VD to element regions Sa2, Sa3, Sa6, Sa7 . . . , from second source line SL2.

Thus, it is possible to inhibit injection of electrons into charge storing layers FG of select gates SGD1 disposed in cell units UC (UC2, UC3, UC6, UC7 . . . ) to be non-selected, even if control circuit CC applies high level voltage Vpgm for programming to select gate line SGL1.

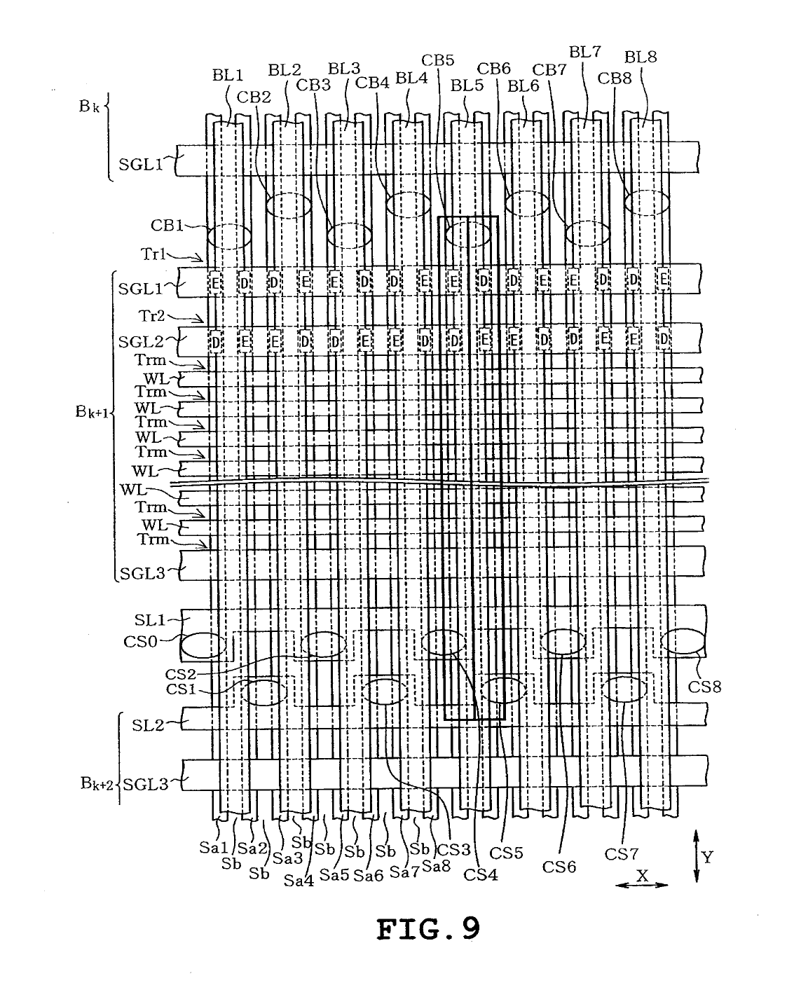

Next, as represented by “E” in FIG. 9, control circuit CC increases the threshold voltage of select transistors trs2 disposed in cell units UC (UC2, UC3, UC6, UC7 . . . ) connected to common second source line SL2 to a threshold voltage within first threshold voltage distribution VHth1 (>second threshold voltage distribution VHth2). As a result, the threshold voltages of select transistors Trs2 disposed in cell units UC (UC2, UC3, UC6, UC7 . . . ) are increased and become type “E” transistors as illustrated in the plan view of FIG. 9.

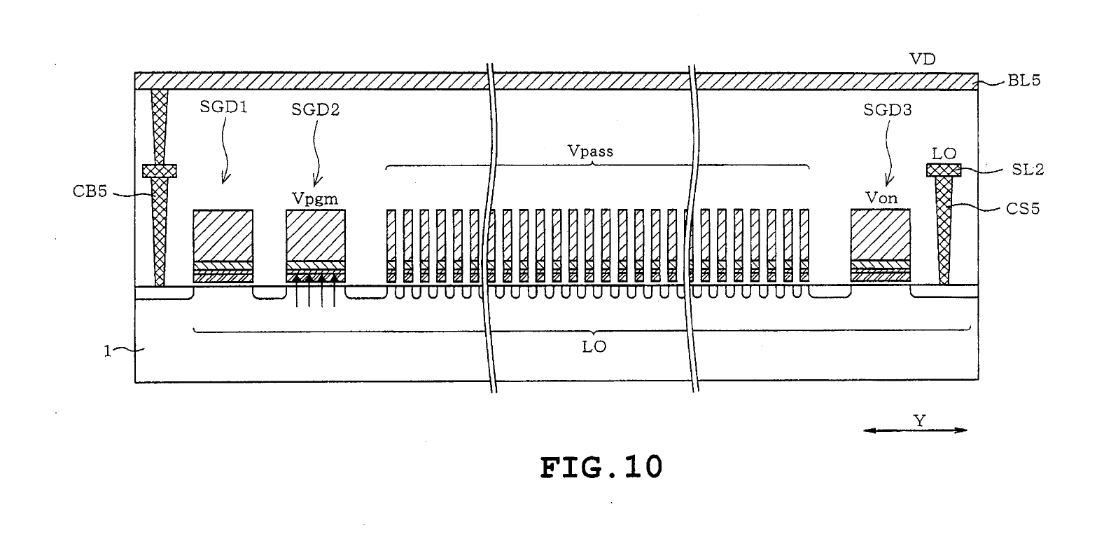

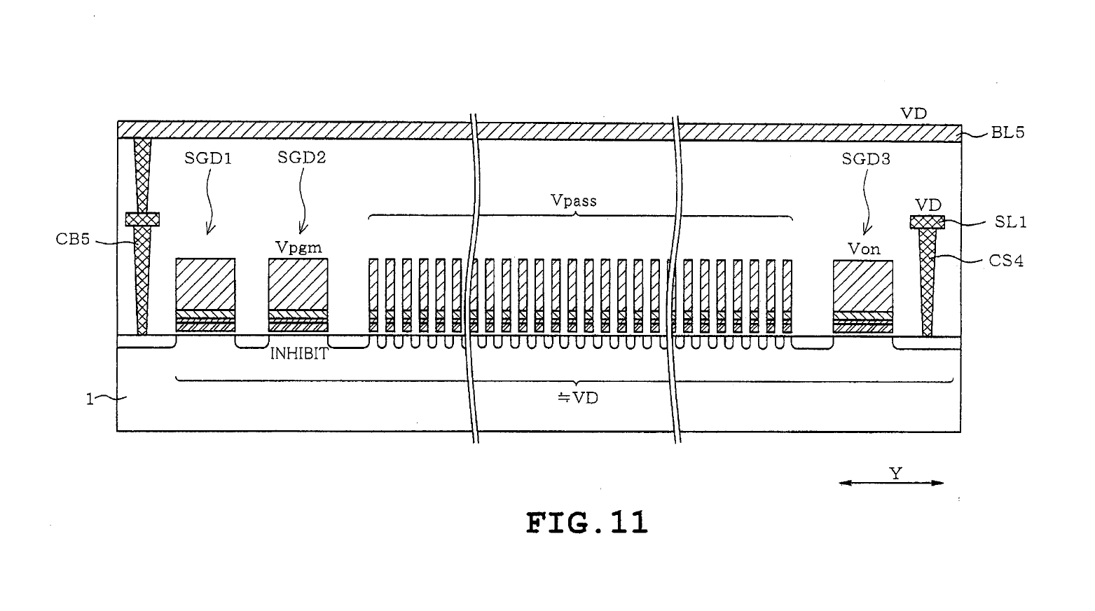

The voltage conditions applied in this control are indicated in FIG. 10 and FIG. 11. FIG. 10 indicates the voltage conditions applied to cell units UC (UC2, UC3, UC6, UC7 . . . ) to be selected. FIG. 11 indicates the voltage conditions applied to cell units UC (UC1, UC4, UC5, UC8 . . . ) to be non-selected.

As illustrated in FIG. 10, control circuit CC applies low level voltage LO (0V for example) to second source line SL2, ON control voltage Von to select gate lines SGL1 and SGL3 for effecting the switch to the ON state, and further applies pass voltage Vpass to all of word lines WL (to WL0 to WL63 in case there are 64 word lines).

Thus, low level voltage LO (≈0V) can be applied from second source line SL2 to element regions Sa2, Sa3, Sa6, Sa7 . . . , by control circuit CC. When high level voltage Vpgm for programming is applied to select gate line SGL2 by the step-up programming process described earlier, it is possible to inject electrons into charge storing layers. FG of select gates SGD2 of selected cell units UC (UC2, UC3, UC6, UC7 . . . ).

At this instance, because control circuit CC of peripheral circuit PC applies power-supply voltage VD to first source line SL1 as illustrated in FIG. 11 in cell units UC (UC1, UC4, UC5, UC8 . . . ) to be non-selected, it is possible to apply a voltage approximating power-supply voltage VD to element regions Sa1, Sa4, Sa5, Sa8 . . . , from first source line SL1.

Thus, it is possible to inhibit injection of electrons into charge storing layers FG of select gates SGD2 disposed in cell units UC (UC1, UC4, UC5, UC8 . . . ) to be non-selected, even if control circuit CC applies high level voltage Vpgm for programming to select gate line SGL2.

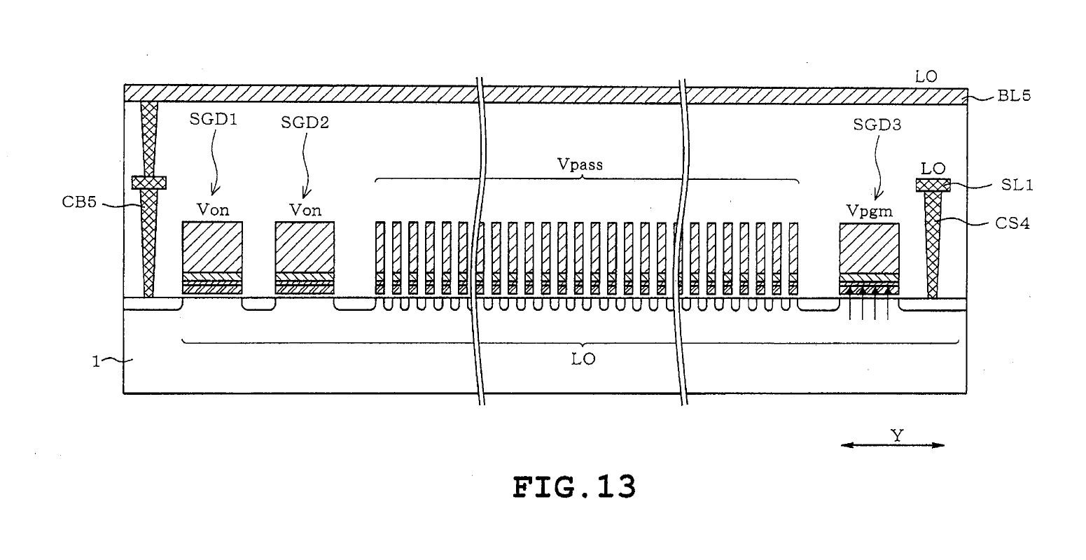

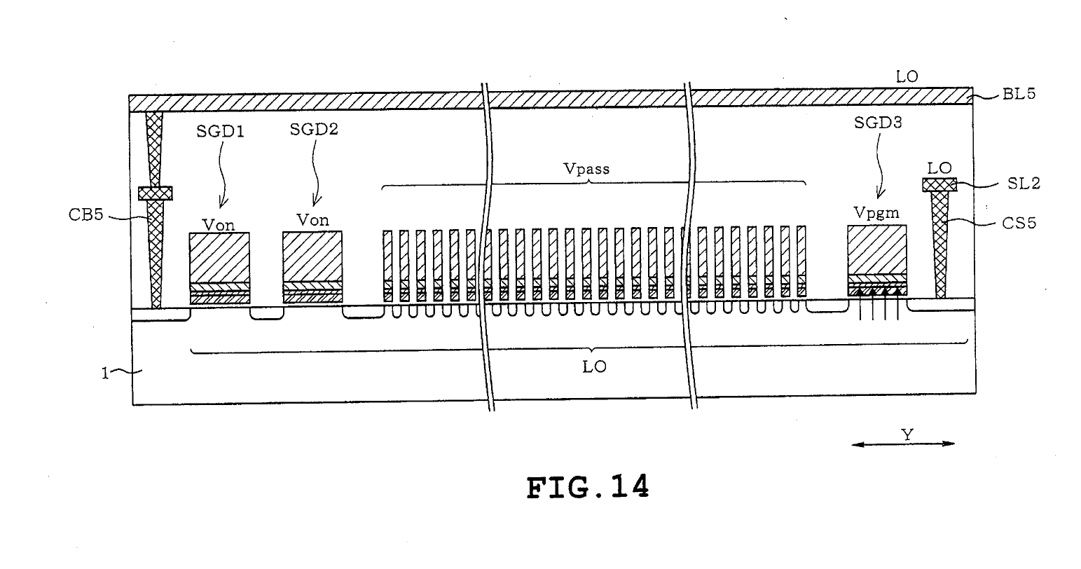

Next, as represented by hatched boxes with broken line boundaries, electrons are injected into charge storing layers FG of select gates SGD3 of select transistors Trs3 disposed in all of cell units UC1 to UCn. FIG. 13 indicates the voltage conditions applied to cell units UC (UC1, UC4, UC5, UC8 . . . ) connected to first source line SL1. FIG. 14 indicates the voltage conditions applied to cell units UC (UC2, UC3, UC6, UC7 . . . ) to be connected to second source line SL2.

As illustrated in FIG. 13, control circuit CC applies low level voltage LO (0V for example) to first source line SL1, low level voltage LO (0V for example) to bit lines BL, ON control voltage Von to select gate lines SGL1 and SGL2, and further applies pass voltage Vpass to all of word lines WL (to WL0 to WL63 in case there are 64 word lines).

Thus, low level voltage LO (≈0V) can be applied from first source line SL1 to element regions Sa1, Sa4, Sa5, Sa8 . . . , by control circuit CC. When high level voltage Vpgm for programming is applied to select gate line SGL3 by control circuit CC under such conditions, it is possible to inject electrons into charge storing layers FG of select gates SGD3 of target cell units UC (UC1, UC4, UC5, UC8 . . . ).

FIG. 14 provides similar illustrations for cell units UC (UC2, UC3, UC6, UC7 . . . ) adjacent to cell units UC (UC1, UC4, UC5, UC8 . . . ). As illustrated in FIG. 14, control circuit CC applies low level voltage LO (0V for example) to second source line SL2, low level voltage LO (0V for example) to bit lines BL, ON control voltage Von to select gate lines SGL1 and SGL2, and further applies pass voltage Vpass to all of word lines WL (to WL0 to WL63 in case there are 64 word lines).

Thus, low level voltage LO (≈0V) can be applied from second source line SL2 to element regions Sa2, Sa3, Sa6, Sa7 . . . , by control circuit CC. When high level voltage Vpgm for programming is applied to select gate line SGL3 by control circuit CC under such conditions, it is possible to inject electrons into charge storing layers FG of select gates SGD3 of selected cell units UC (UC2, UC3, UC6, UC7 . . . ). The processes illustrated in FIG. 13 and FIG. 14 may be carried out separately or simultaneously but are preferably carried out simultaneously.

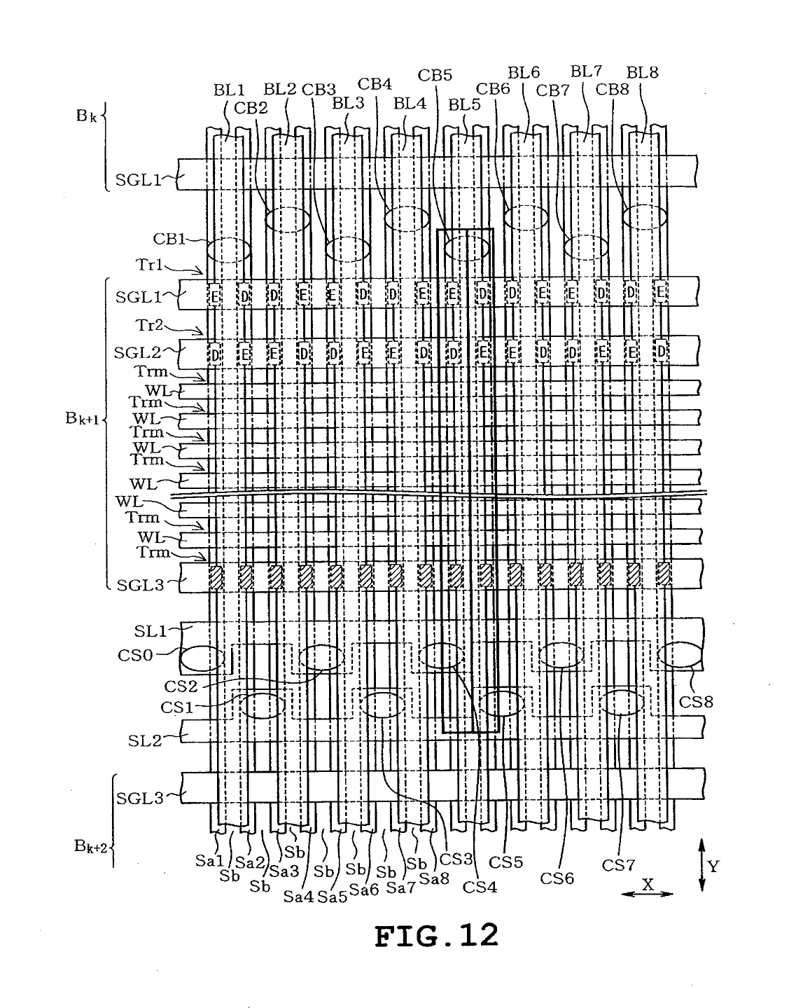

Further, the processes illustrated in FIG. 6 to FIG. 8, FIG. 9 to FIG. 11, and FIG. 12 to FIG. 14 may be carried out in this order or may be interchanged. It is possible to specify threshold voltages Vth of select transistors Trs1, Trs2, and Trs3 within multiple threshold voltage distributions (within first threshold voltage distribution VHth1 or second threshold voltage distribution VHth2) in the above described manner.

A method of programming memory-cell transistors Trm of the first embodiment will be described hereinafter. By employing the connection scheme of the first embodiment, it is possible to select programming cell units in the unit of four adjacent cell units. In this example, one cell unit is selected as the programming target from cell units UC3 to UC6.

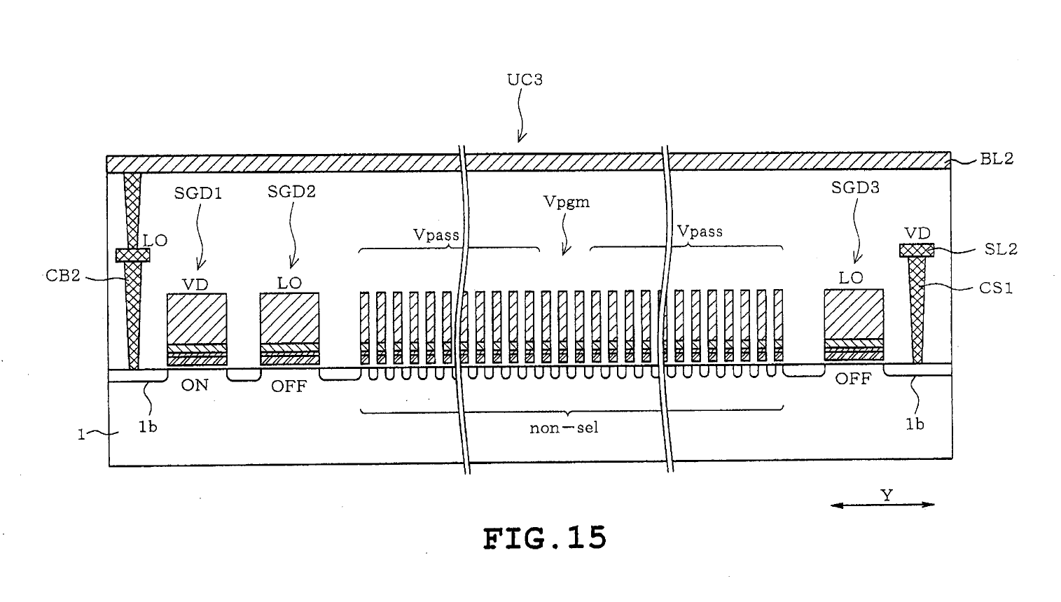

FIG. 15 to FIG. 18 indicate the voltage conditions applied to each of cell units UC3 to UC6 when control circuit CC applies power-supply voltage VD to select gate line SGL1 and low level voltage LO (≈0V) to select gate lines SGL2.

In cell unit UC3, the threshold voltage of select transistor Trs1 is specified within second threshold voltage distribution VHth2 and the threshold voltage of select transistor Trs2 is specified within first threshold voltage distribution VHth1.

As illustrated in FIG. 15, when control circuit CC applies power-supply voltage VD to select gate line SGL1 and low level voltage LO (≈0V) to select gate lines SGL2 and SGL3, select transistors Trs2 and Trs3 are turned OFF. Thus, cell string SC of cell unit UC3 become non-selected.

In cell units UC4 and UC5, the threshold voltage of select transistor Trs1 is specified within first threshold voltage distribution VHth1 and the threshold voltage of select transistor Trs2 is specified within second threshold voltage distribution VHth2.

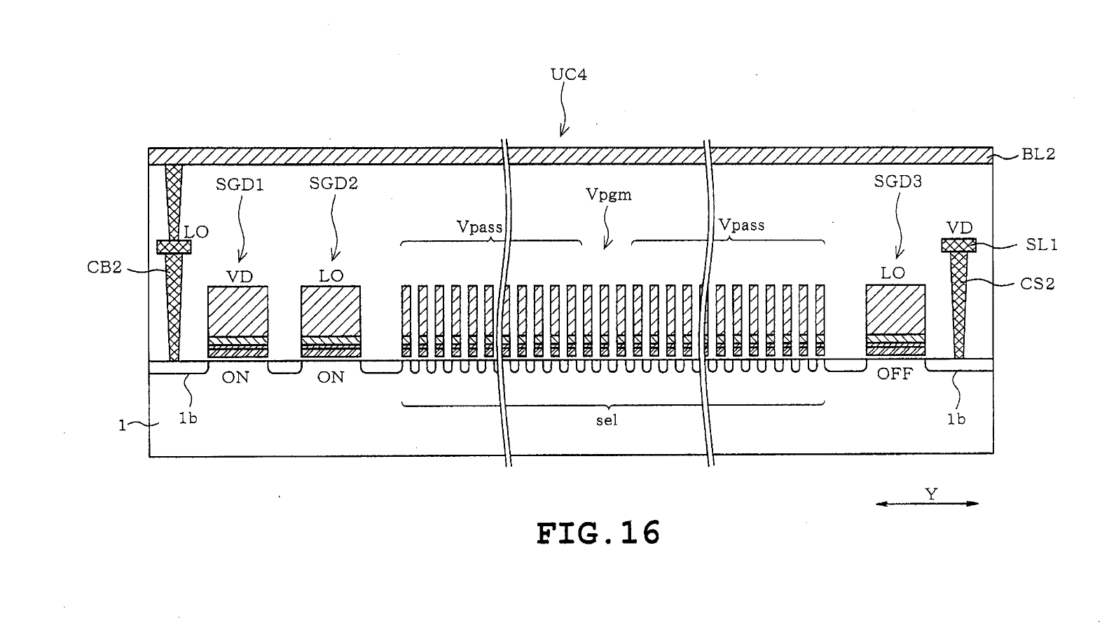

As illustrated in FIG. 16, when control circuit CC applies power-supply voltage VD to select gate line SGL1 and low level voltage LO (≈0V) to select gate lines SGL2, both select transistors Trs1 and Trs2 are turned ON. Thus, cell string SC of cell unit UC4 become selected. Control circuit CC applies power-supply voltage VD to select gate line SGL1.

Control circuit CC controls the voltage level of bit line BL2 based on the data to be programmed. For example, control circuit CC applies low level voltage LO to bit line BL2 when it is required to increase the threshold voltage of memory-cell transistor Trm targeted for programming, and applies power-supply voltage VD to bit line BL2 when it is required to maintain the threshold voltage of memory-cell transistors Trm targeted for programming.

FIG. 16 describes the case in which the threshold voltage of memory-cell transistor Trm targeted for programming is increased by giving low level voltage LO to bit line BL2. When control circuit CC applies pass voltage Vpass to memory-cell transistors Trm which are untargeted for programming; and high level programming voltage Vpgm to word line WL of memory-cell transistor trm targeted for programming; low level voltage LO is applied to the channel region of memory-cell transistor Trm. As a result, it becomes possible to write data into memory-cell transistor Trm targeted for programming in cell unit UC4.

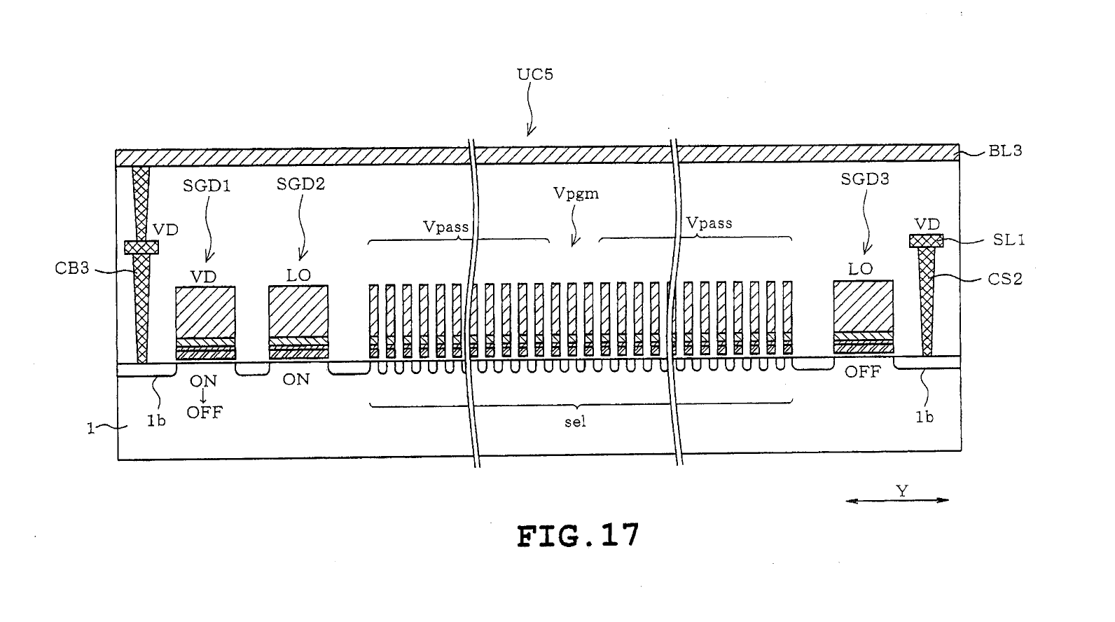

As illustrated in FIG. 17, when control circuit CC applies power-supply voltage VD to select gate line SGL1 and low level voltage LO (≈0V) to select gate line SGL2, both select transistors Trs1 and Trs2 are turned ON. Thus, cell string SC of cell unit UC5 become selected. Control circuit CC applies power-supply voltage VD to first source line SL1.

Control circuit CC controls the voltage level of bit line BL3 based on the data to be programmed to memory-cell transistor Trm. FIG. 17 describes the case in which the threshold voltage of memory-cell transistor Trm targeted for programming is maintained by giving power-supply voltage VD to bit line BL3. Power-supply voltage VD applied to bit line BL3 is transferred to the channel region of memory-cell transistor Trm untargeted for programming. Transistor Trs1 is thereafter turned OFF.

Thus, when control circuit CC applies pass voltage Vpass to memory-cell transistors Trm which are untargeted for programming; and high level programming voltage Vpgm to word line WL of memory-cell transistor trm targeted for programming, power-supply voltage VD transferred to the channel region of memory-cell transistor Trm is increased by coupling. Thus, it is possible to inhibit increase of the threshold voltage of memory-cell transistor Trm even when programming voltage Vpmg is applied. As a result, it is possible to maintain the threshold voltage of memory-cell transistor Trm targeted for programming disposed in cell unit UC5.

In cell units UC6, the threshold voltage of select transistor Trs1 is specified within second threshold voltage distribution VHth2 and the threshold voltage of select transistor Trs2 is specified within first threshold voltage distribution VHth1.

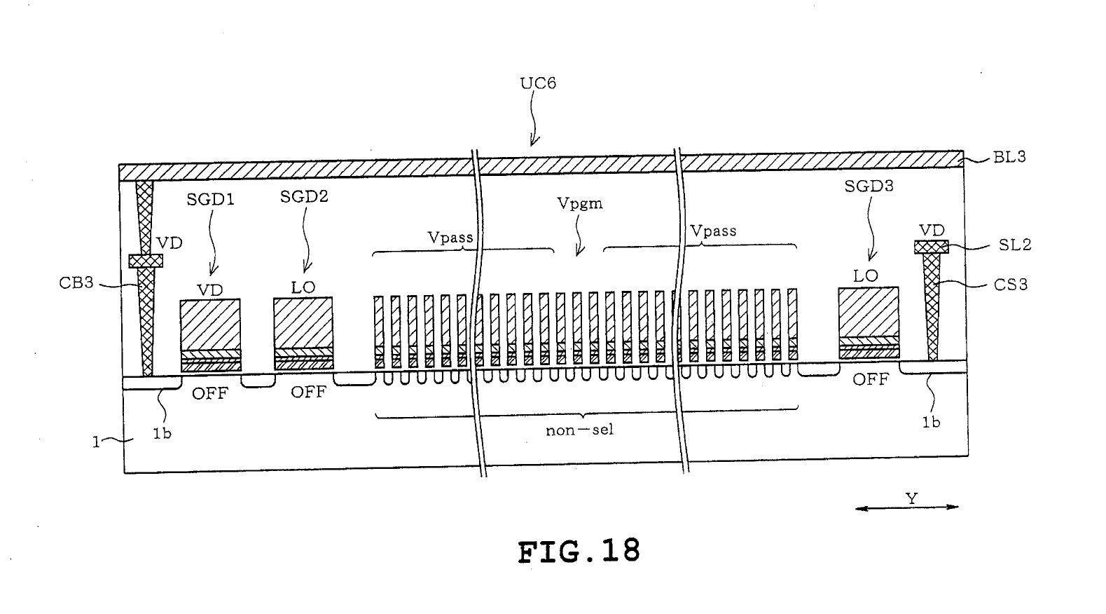

As illustrated in FIG. 18, both select transistors Trs1 and Trs2 in cell unit UC6 are turned OFF and cell string SC of cell unit UC6 become non-selected.

Thus, it is possible to specify cell units UC4 and UC5 as selected cell units among the four cell units UC3 to UC6 and control the data to be written based on the voltage applied to bit line BL. Further, it is possible to select either of cell units UC3 to UC6 through modification of biasing conditions of first and second source lines SL1 and SL2 and bit lines BL2 and BL3. This will not be described as the descriptions given heretofore may be re-applied.

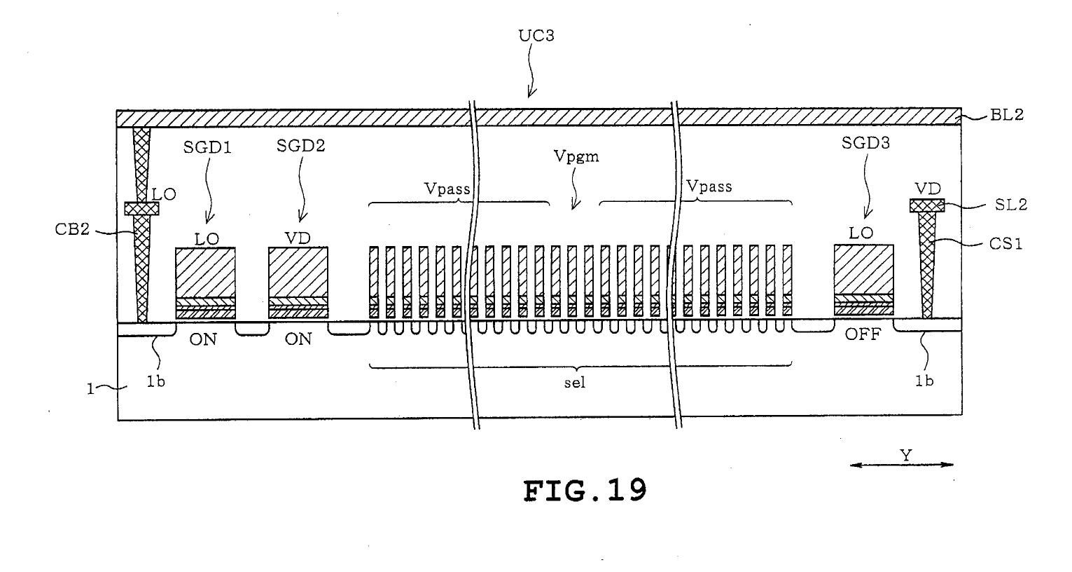

FIG. 19 to FIG. 22 illustrate the voltage conditions of each of cell units UC3 to UC6 when control circuit CC applies low level voltage LO (≈0V) to select gate line SGL1 and power-supply voltage VD to select gate line SGL2.

As illustrated in FIG. 19, when control circuit CC applies low level voltage LO (≈0V) to select gate lines SGL1, power-supply voltage VD to select gate line SGL2, and low level voltage LO (≈0V) to select gate lines SGL3, both select transistors Trs1 and Trs2 of cell unit UC3 are turned ON. Thus, cell string SC of cell unit UC3 become selected.

Control circuit CC controls the voltage level of bit line BL2 based on the data to be programmed to memory-cell transistor Trm. FIG. 19 describes the case in which the threshold voltage of memory-cell transistor Trm targeted for programming is increased by giving low level voltage LO to bit line BL2. When control circuit CC applies pass voltage Vpass to word lines WL of memory-cell transistors Trm which is untargeted for programming; and high level programming voltage Vpgm to word line WL of memory-cell transistor trm targeted for programming; low level voltage LO is applied to the channel region of memory-cell transistor Trm. As a result, it becomes possible to write data into memory-cell transistor Trm targeted for programming in cell unit UC3.

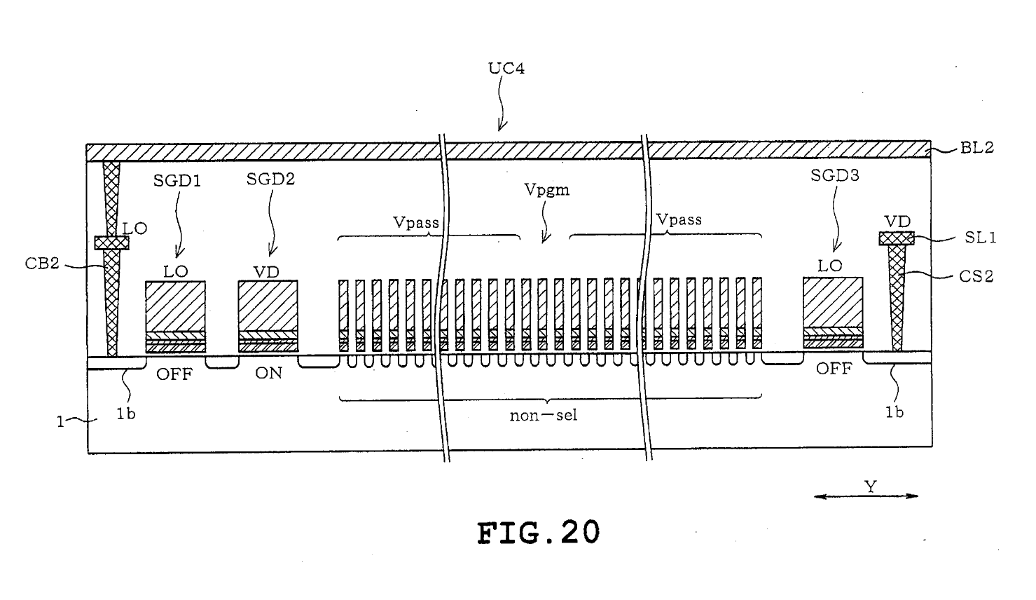

As illustrated in FIG. 20, when control circuit CC applies low level voltage LO (≈0V) to select gate lines SGL1, power-supply voltage VD to select gate line SGL2, and low level voltage LO (≈0V) to select gate lines SGL3, select transistor Trs1 of cell unit UC4 is turned OFF while select transistor trs2 is turned ON. Because select transistor Trs3 is turned OFF, cell string SC of cell unit UC4 is non-selected.

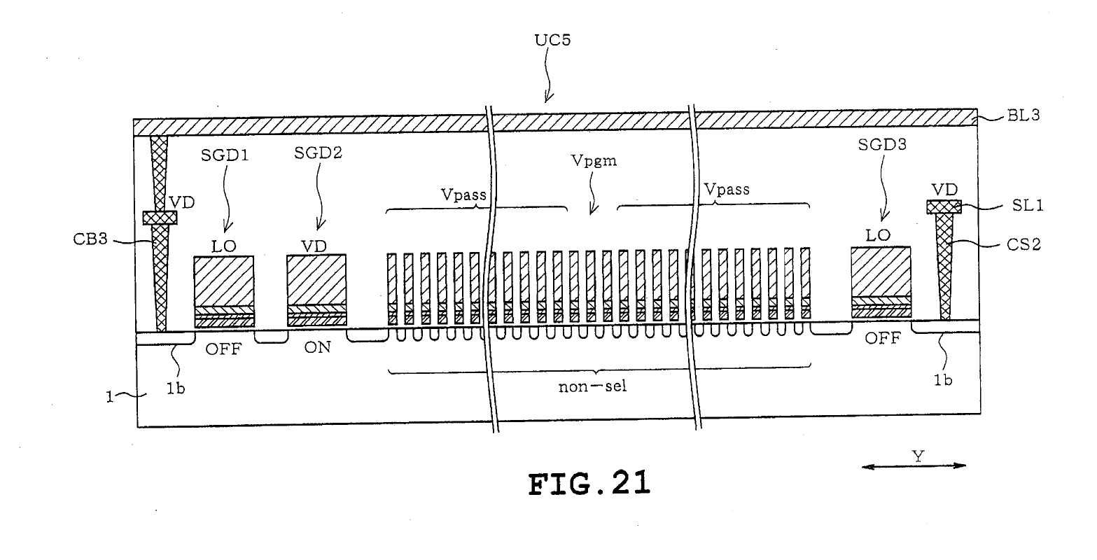

As illustrated in FIG. 21, control circuit CC applies power-supply voltage VD to bit line BL3 in cell unit UC5; however, select transistor Trs1 is turned OFF. Thus, cell string SC of cell unit UC5 become non-selected.

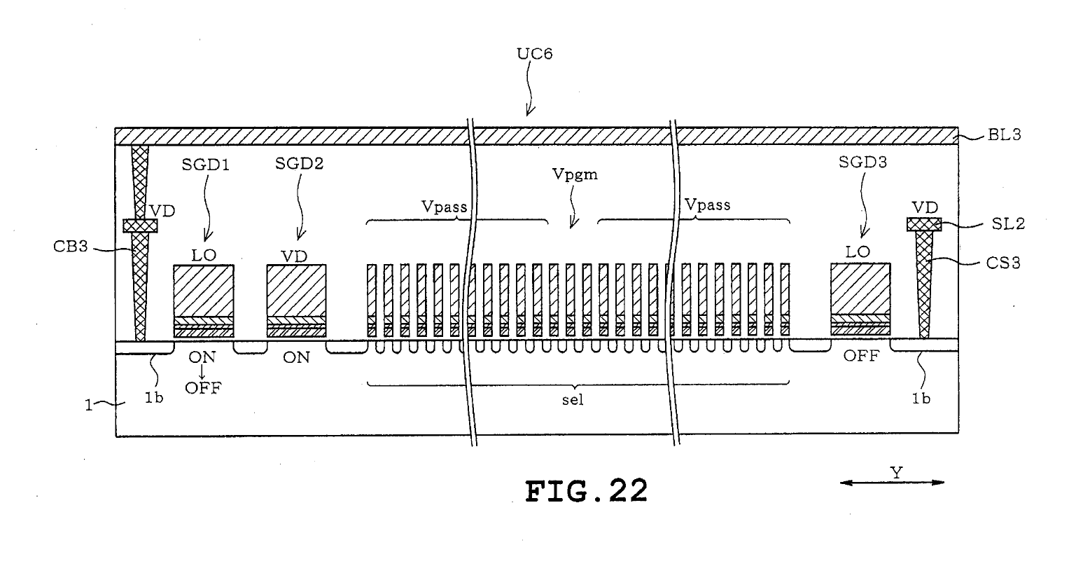

As illustrated in FIG. 22, both select transistors Trs1 and Trs2 are turned ON in cell unit UC6. Thus, cell string SC of cell unit UC6 become selected. Control circuit CC applies power-supply voltage VD to second source line SL2.

Control circuit CC controls the voltage level of bit line BL3 based on the data to be programmed to memory-cell transistor Trm. FIG. 22 describes the case in which the threshold voltage of memory-cell transistor Trm targeted for programming is maintained by giving power-supply voltage VD to bit line BL3.

Power-supply voltage VD applied to bit line BL3 is transferred to the channel region of memory-cell transistors Trm untargeted for programming. Transistor Trs1 is thereafter turned OFF. Control circuit CC applies pass voltage Vpass to memory-cell transistors Trm which is untargeted for programming; and high level programming voltage Vpgm to word line WL of memory-cell transistor trm targeted for programming, power-supply voltage VD transferred to the channel region of memory-cell transistor Trm is increased by coupling. Thus, it is possible to inhibit increase of the threshold voltage of memory-cell transistor Trm. As a result, it is possible to maintain the threshold voltage of memory-cell transistors Trm targeted for programming disposed in cell unit UC6.

Under such biasing conditions, it is possible to specify cell units UC3 and UC6 as selected cell units among the four cell units UC3 to UC6 and control the data to be written based on the voltage applied to bit line BL. Further, it is possible to selectively program either of memory-cell transistors Trm through modification of biasing conditions of first and second source lines SL1 and SL2 and bit lines BL2 and BL3.

In the first embodiment, one bit line BLs is disposed for every two adjacent element regions Sa instead of providing one bit line BLs for every one element region Sa. Further, bit line BLs is configured to have a large width as well as a large pitch width approximately twice the pitch width of element region Sa. Asa result, it is possible to suppress signal delays of bit lines BLs.

Further, because one bit-line contact CB is formed for every two element regions Sa, it is possible to increase the diameter of bit-line contact CB and thereby prevent contact failure between bit-line contact CB and semiconductor substrate 1 as much as possible.

Further, it is possible to control threshold voltages Vth of select transistors Trs1, Trs2, and Trs3 because the control circuit CC is configured to inject electrons into charge storing layers FG of select gates SGD1, SGD2, and SGD3. In the first embodiment, select transistors Trs1, Trs2, and Trs3 of cell units UC can be configured without forming an opening through IPD film 5 of select gates SGD1, SGD2, and SGD3. It is further possible to specify threshold voltages Vth of select transistors Trs1, Trs2, and Trs3, free of openings in IPD film 5, by pre-programming select gates SGD1, SGD2, and SGD3 in the test step prior to shipment. As a result, it is possible to simplify the manufacturing process flow.

Select transistors Trs1 of cell units UC1 and UC4 as well as select transistors Trs2 of cell units UC2 and UC3 are controlled to a substantially equal threshold voltage represented as threshold voltage Vth1. Select transistors Trs2 of cell units UC1 and UC4 as well as select transistors Trs1 of cell units UC2 and UC3 are controlled to a substantially equal threshold voltage represented as threshold voltage Vth2. Threshold voltage Vth1 and threshold voltage Vth2 fall within different threshold distributions, namely threshold distribution VHth1 and threshold distributions VHth2, respectively.

As a result, it is possible to uniquely select either cell unit from cell units UC (UC1 and UC2, UC3 and UC4) connected to a common bit line.

It is further possible to control the threshold voltages of select transistors Trs1, Trs2, and Trs3 based on the process flow indicated in FIG. 4. As a result, the threshold voltages of select transistors Trs1, Trs2, and Trs3 need not be controlled by ion implantation or the like.

As a result, it is possible to reduce the dose of boron (B) ions introduced into the regions below select gates SGD1, SGD2, and SGD3 and thereby reduce GIDL (Gate Induced Drain Leakage) occurring in non-selected cell units. It is further possible to reduce the resistance in the region below bit-line contact CB.

Because both select gate lines SGL1 and SGL2 can be formed to extend in a straight line in the X direction in for example the same layer level, it is possible to facilitate the patterning of wiring patterns.

### Second Embodiment

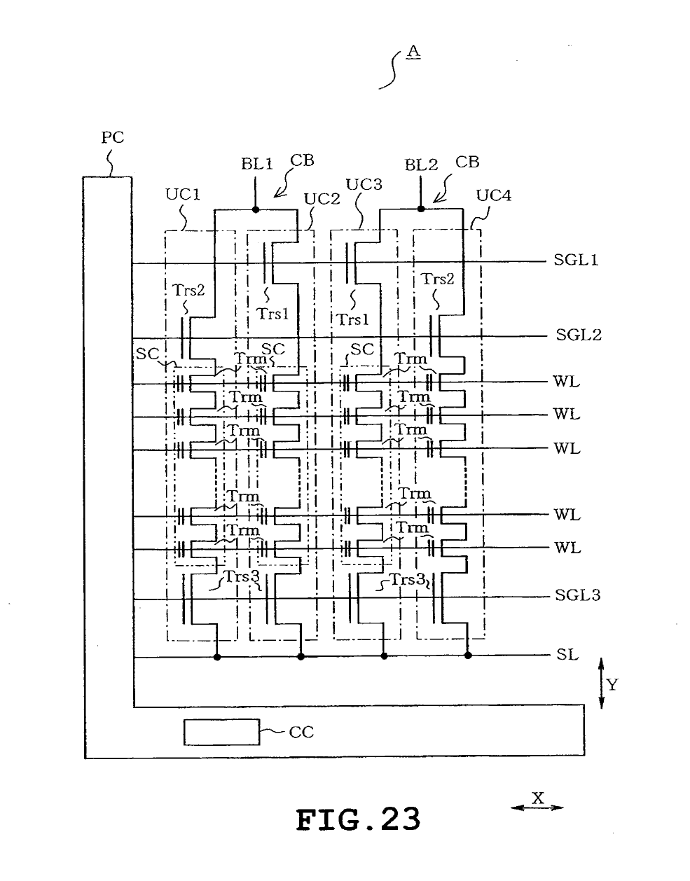

FIG. 23 to FIG. 34 illustrate a second embodiment. In the second embodiment, the formation of structures of select gates SGD1, SGD2, and SGD3 take place at different timing from the formation of gates MG. As a result, it is possible to form select gates (especially select gates SGD1 and SGD2) without forming an opening through IPD film 5.

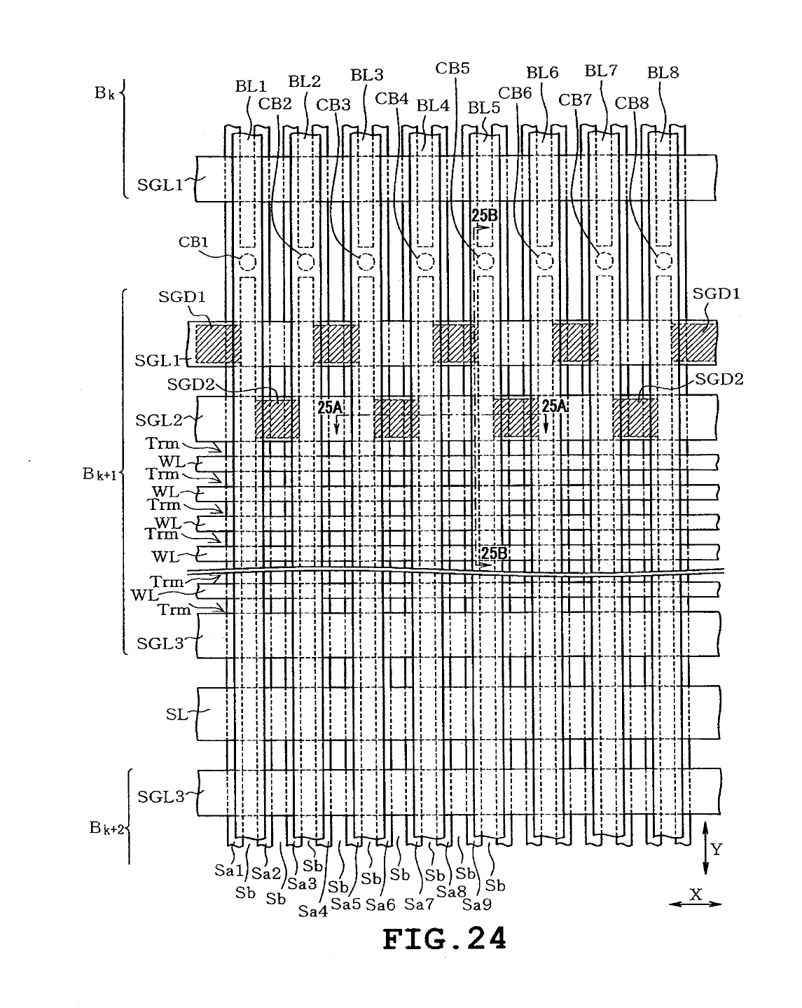

FIG. 23 schematically illustrate the electrical configuration of the second embodiment. FIG. 24 is a plan view schematically and partially illustrating the layout of block B of the second embodiment. A description will be given hereinafter on the structure and connection of the wirings of the multiplicity of cell units UC1 to UCn disposed in the X direction through an example of a given block B.

As illustrated in FIG. 23, cell units UC2, UC3, UC6, UC7, . . . , UC4n-2, and UC4n-1 are each provided with a couple of select transistors Trs1 and Trs3 and multiplicity (64 for example) of memory-cell transistors Trm series connected between select transistors Trs1 and Trs3. Memory-cell transistors Trm series connected between select transistors Trs1 and Trs3 serves as cell string SC.

Similarly, cell units UC1, UC4, UC5, UC8, . . . , UC4n-3, and UC4n are each provided with a couple of select transistors Trs2 and Trs3 and multiplicity (64 for example) of memory-cell transistors Trm series connected between select transistors Trs2 and Trs3. Memory-cell transistors Trm series connected between select transistors Trs2 and Trs3 also serves as cell string SC.

Select gates SGD1 of select transistors Trs1 provided in cell units UC2, UC3, UC6, UC7, . . . , UC4n-2, and UC4n-1 are connected to a common select gate line SGL1. Similarly, select gates SGD2 of select transistors Trs2 provided in cell units cell units UC1, UC4, UC5, UC8, . . . , UC4n-3, and UC4n are connected to a common select gate line SGL2. Further, select gates SGD3 of select transistors Trs3 provided in cell units UC1 to UC4n are connected to a common select gate line SGL3.

As illustrated in FIG. 24, two element regions Sat−1 and Sat adjacent in the X direction are linked in the region located between select gate line SGL1 belonging to block Bk and select gate line SGL1 belonging to block Bk+1. A single bit-line contact CBs is provided above the linking portion disposed between the two element regions Sat−1 and Sat adjacent in the X direction. A single bit line BLs is provided above the single bit-line contact CBs. Bit line BLs is provided for every two adjacent element regions Sat−1 and Sat and is configured as the so-called shared bit-line structure.

As was the case in the first embodiment, each of cell units UC1 to UCn in a single block Bk+1 is disposed so as to appear to be folded back in the Y direction at the region where each of bit-line contacts CB are formed so as to be in line symmetry with one another. Similarly, each of cell units UC1 to UCn in a single block Bk+1 is disposed so as to appear to be folded back in the Y direction at the region where each of source-line contacts CS (region where source line SL is formed) are formed so as to be in line symmetry with one another. The primary differences from the first embodiment are the structure of source line SL and the layout of select gates SGD1 and SGD2.

As illustrated in FIG. 24, source line SL is disposed in the Y direction center of the region located between select gate line SGL3 of block Bk+1 and select gate line SGL3 of block Bk+2 adjacent to one another. Unlike the first embodiment, source line SL is configured as a wiring that extends in the X direction while establishing contact with the upper surface of semiconductor substrate 1.

Select gate SGD1 is formed as a single electrode disposed continuously between element regions Sa4 and Sa5, between Sa8 and Sa9, and so forth of adjacent even number and odd number cell units UC (such as UC4 and UC5, UC8 and UC9, or the like) that do not share bit line BLs.

As a result, ON/OFF control of element regions Sa4 and Sa5, Sa8 and Sa9, and so forth of semiconductor substrate 1 can be carried out simultaneously by applying a high level voltage to select gate line SGL1 through control circuit CC.

Select gate SGD2 is formed as a single electrode disposed continuously between element regions Sa2 and Sa3, between Sa6 and Sa7, and so forth of adjacent even number and odd number cell units UC (such as UC2 and UC3, UC6 and UC7, or the like) in which select gate SD1 is not formed and that do not share bit line BLs.

As a result, ON/OFF control of element regions Sa2 and Sa3, Sa6 and Sa7, and so forth of semiconductor substrate 1 can be carried out simultaneously by applying a high level voltage to select gate line SGL2 through control circuit CC.

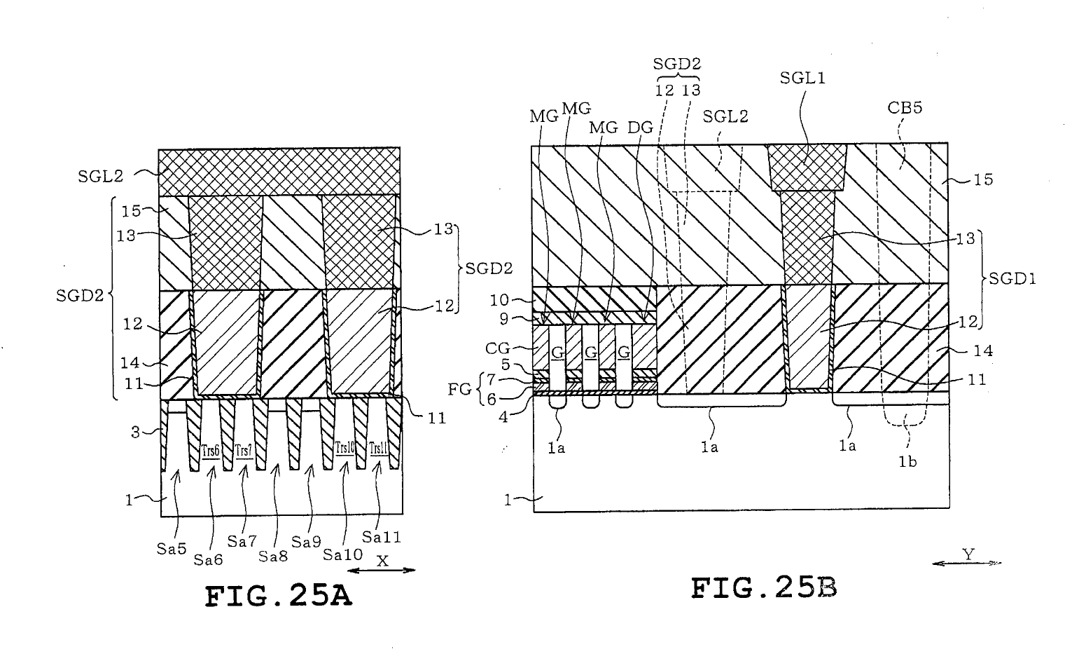

FIG. 25A and FIG. 25B are vertical cross-sectional side views taken along line 25A-25A and line 25B-25B of FIG. 24, respectively. Semiconductor substrate 1 is formed of a P-type silicon substrate for example having element isolation regions Sb, taking an STI structure, extending in the Y direction as viewed in FIG. 24. Element regions Sa1 to San of cell units UC1 to UCn are isolated from one another by element isolation regions Sb and extend in the Y direction. Element regions Sa1 to San have equal X-direction width and are spaced from one another by equal X-direction distance.

As illustrated in the cross section (the cross section taken along line 25A-25A of FIG. 24) of FIG. 25A, select gate SGD2 is formed in adjacent element regions Sa6 and Sa7 of semiconductor substrate 1 via gate insulating film 11. Select transistor Trs6 is provided with select gate SGD2 in element region Sa6 via gate insulating film 11. Select transistor Trs7 is provided with select gate SGD2 in element region Sa7 via gate insulating film 11. Select gate SGD2 is shared by select transistor Trs6 and select transistor Trs7.

Another select gate SGD2 is disposed in element isolation region Sa10 and Sa11 which is two element regions (element regions Sa8 and Sa9) apart in the X direction from select gate SGD2 disposed in element regions Sa6 and Sa7. That is, select gate SGD2 is formed in two adjacent element regions Sa10 and Sa11 of semiconductor substrate 1 via gate insulating film 11. Select transistor Trs10 is provided with select gate SGD2 in element region Sa10 via gate insulating film 11. Select transistor Trs11 is provided with select gate SGD2 in element region Sa11 via gate insulating film 11. Select gate SGD2 is shared by select transistor Trs10 and select transistor Trs11.

Though not illustrated in the cross section of FIG. 25A, select gate SGD1 is formed in the two element regions Sa8 and Sa9 via gate insulating film (not illustrated).

Select gate SGD2 is configured as a stack of embedded conductive films 12 and 13. Interlayer insulating films 14 and 15 are stacked above semiconductor substrate 1 and element isolation film 3. A hole is formed through interlayer insulating film 14 for filling conductive film 12 and a hole is formed through interlayer insulating film 15 for filling conductive film 13. Gate insulating film 11 is formed along the inner surface of the hole formed through interlayer insulating film 14.

Conductive film 12 is filled along gate insulating film 11 lined along the hole extending through interlayer insulating film 14. Conductive film 13 is filled in the hole extending through interlayer insulating film 15 so as to be disposed above conductive film 12. Conductive film 16 is disposed above and across conductive films 13 of multiple select gates SGD2 in the X direction and serves as select gate line SGL2.

As illustrated in FIG. 25B, gate MG of memory-cell transistor Trm is configured as a stack structure as was the case in the first embodiment. The stack structure includes, from the bottom of the stack, polysilicon film 6 formed above tunnel oxide film 4, charge trap film 7, IPD film 5, and conductive layer 8. Polysilicon film 6 serves as a conductive film and conductive layer 8 serves as control electrode CG and word line WL. The thin polysilicon film 6 and charge trap film 7 serve as charge storing layer and takes the so-called flat-floating-gate cell structure.

Air gaps G may be provided between gates MG. An insulating film 9 is formed so as to cover gates MG. Interlayer insulating film 10 is formed above insulating film 9, and interlayer insulating film 15 is further formed above interlayer insulating film 10.

Diffusion regions 1a may be provided in the surface layer of semiconductor substrate 1 located on both sides of each gate MG. Diffusion region 1a serves as the source/drain region of each memory-cell transistor Trm. Further, as illustrated in FIG. 25B, select gate SGD1 is provided so as to be spaced in the Y direction from gate MG of memory-cell transistor Trm.

Select gate SGD1 is configured as a stack of conductive films 12 and 13. Gate insulating film 11 also covers the Y-direction side surfaces of conductive film 12. Diffusion regions 1a and 1b are formed in the surface layer of semiconductor substrate 1 located on both Y-direction sides of select gate SGD1.

Bit-line contact CB5 is formed above the upper surface of heavily-doped diffusion region 1b. Bit-line contact CB5 is not visible in the cross section taken along line 25B-25B of FIG. 24 and thus, is indicated by broken line in FIG. 25B for a comparative look in the surface direction of semiconductor substrate 1.

A description will be given on a programming process of the second embodiment with reference to FIG. 23. The programming process operates in the unit of 4 cell units UC such as cell units UC1 to UC4. The programming process will be described hereinafter through an example of cell units UC1 to UC4.

For example, when control circuit CC provided in peripheral circuit PC applies power-supply voltage VD to select gate line SGL1 and low level voltage (≈0V) to select gate lines SGL2 and SGL3, select transistor Trs1 is turned ON while select transistors Trs2 and Trs3 are turned OFF.

When select transistor Trs1 is turned ON, bit line BL1 and cell unit UC2 become conductive and cell unit UC2 is selected. Similarly, when select transistor Trs1 is turned ON, bit line BL2 and cell unit UC3 become conductive and cell unit UC3 is selected.

On the other hand, since select transistors Trs2 are turned OFF, bit line BL1 and cell unit UC1 as well as bit line BL2 and cell unit UC4 become nonconductive. As a result, cell units UC1 and UC4 are non-selected.

Control circuit CC controls the voltage level of bit line BL based on the data to be programmed to memory-cell transistor Trm. For example, control circuit CC applies low level voltage LO to bit line BL2 when it is required to increase the threshold voltage of memory-cell transistors Trm of cell unit UC3. As a result, the low level voltage LO (≈0V) applied to bit line BL2 is transferred to the channels of memory-cell transistors Trm of cell unit UC3.

Thus, when control circuit CC applies a high level voltage to word line WL of each of transistors Trm as programming voltage Vpgm, tunneling current flows through tunnel insulating film 4 to consequently allow electrons to be injected into charge storing layer FG, meaning that, it is possible to increase the threshold voltage of memory-cell transistors Trm of cell unit UC3.

In contrast, control circuit CC applies power-supply voltage VD to bit line BL1 when it is required to maintain the threshold voltage of memory-cell transistors Trm of cell unit UC2. As a result, power-supply voltage VD is transferred to the channels of memory-cell transistors Trm of cell unit UC2 whereafter select transistor Trs1 is turned OFF.

Thus, when control circuit CC applies a high level voltage to word line WL of each of transistors Trm as programming voltage Vpgm, power-supply voltage VD transferred to the channels of memory-cell transistors Trm is increased by coupling. As a result, it is possible to inhibit injection of electrons into charge storing layer FG of memory-cell transistors Trm of cell unit UC2. Thus, it is possible to maintain the threshold voltage of memory-cell transistors Trm of cell unit UC2.

Further, because select transistors Trs2 of cell units UC1 and UC4 are turned OFF, the potential of the channels of memory-cell transistors Trm are increased by coupling when control circuit CC applies high level voltage to word line WL of each transistor Trm as programming voltage Vpgm. As a result, it is possible to inhibit injection of electrons into charge storing layer FG of each of memory-cell transistors Trm of cell units UC1 and UC4, meaning that it is possible to non-select cell units UC1 and UC4 for programming (inhibit from programming).

As described above, it is possible to select cell units UC2 and UC3 for programming from cell units UC1 to UC4 since control circuit CC controls the voltage level of bit line BL based on the data to be programmed and applies power-supply voltage VD to select gate line SGL1 while applying low level voltage (≈0V) to select gate line SGL2. Though not described, it is possible to select either of the cell units of the memory-cell units connected to a common bit line BL for programming since control circuit CC varies the level of voltage applied to bit lines BL1 and BL2, and select gate lines SGL1, SGL2, and SGL3.

In the second embodiment, select gates SGD1 and SGD2 are disposed in zigzag layout and the layout pitch of select gates SGD1 and SGD2 are double of the layout pitch of each of element regions Sa1 to San. Select gate line SGL1 establishes connection with select gates SGD1 connected to element regions Sa1 and Sa4 while passing over element regions Sa2 and Sa3. Select gate line SGL2 establishes connection with select gate SGD2 connected to element regions Sa2 and Sa3 while passing over element regions Sa1 and Sa4.

It is possible to apply voltages (0, VD) to select gate SGD1 through select gate line SGL1 and voltages (0, VD) to select gate SGD2 through select gate line SGL2. It is possible to independently control the selection of the two element regions Sa sharing bit line BLs when programming/reading, since control circuit CC is configured to control the voltages applied to select gates SGD1 and SGD2 separately.

Because both select gate lines SGL1 and SGL2 can be formed in a straight line extending in the X direction which are disposed in the same layer level for example, it is possible to facilitate the patterning of the wiring patterns.

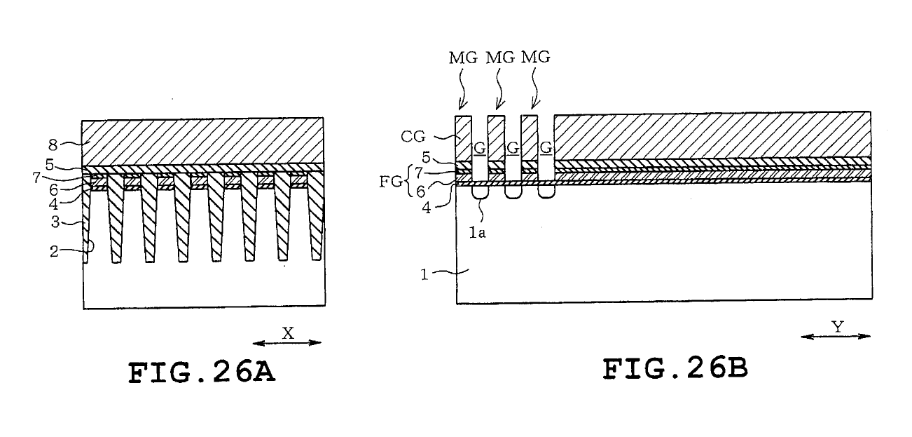

One example of a manufacturing process flow of the second embodiment will be described with reference to the cross sectional views of FIG. 26A to FIG. 34A illustrating the process steps. FIG. 26A to 34A each schematically illustrate one phase of the manufacturing process flow for forming the cross-sectional structure of the main portion of the memory-cell region corresponding to FIG. 25A.

FIG. 26B to 34B each schematically illustrate one phase of the manufacturing process flow for forming the cross-sectional structure of the main portion of the memory-cell region corresponding to FIG. 25B. The following description will focus on the features of the third embodiment. However, process steps that are required for implementation or that are known may be further incorporated between the process steps discussed below. Further, the discussed process steps may be rearranged if practicable.

The manufacturing process flow for obtaining the cross sectional structures illustrated in FIG. 26A and FIG. 26B will be described only briefly in order to focus on the features of the manufacturing process flow of the second embodiment.

First, tunnel oxide film 4 is formed above the surface of semiconductor substrate 1 by forming, for example, a silicon oxide film by thermal oxidation. Tunnel oxide film 4 may be approximately 5 to 8 nm thick for example. Tunnel oxide film 4 is formed as a tunnel oxide film (gate insulating film) for memory-cell transistor Trm.

Above tunnel oxide film 4, silicon film 6 is formed for example by CVD (Chemical Vapor Deposition). The thickness of silicon film 6 is controlled to approximately 10 nm or less for example. Silicon film 6 is formed as an amorphous silicon but is later transformed into a polysilicon by thermal treatment. Above silicon film 6, charge trap film 7 is formed in a thickness of approximately 10 nm or less for example. Materials such as a silicon nitride (SiN), hafnium oxide (HfO), or the like may be used as charge trap film 7.

Above charge trap film 7, an oxide film or the like (not illustrated) is formed which serves as a hard mask for forming element isolation trenches. A resist is formed above the hard mask and thereafter patterned, followed by anisotropic etching using RIE or the like to form element isolation trenches 2.

Then, element isolation trenches 2 are filled with element isolation film 3 by CVD for example. Element isolation film 3 is thereafter planarized by CMP (Chemical Mechanical Polishing). Next, IPD film 5 is formed above the upper surface of element isolation film 3 and above the upper surface of charge trap film 7 by CVD, ALD, or the like. IPD film 5 may be a single layer film formed of for example a silicon nitride (SiN), a silicon oxide (SiO₂), a hafnium oxide (HfO), or an aluminum oxide (AlO). Alternatively, IPD film 5 may be a composite film formed of a combination of two or more of the foregoing materials.

Then, conductive layer 8 is formed above IPD film 5. Conductive layer 8 may comprise a barrier metal and a metal material formed via the barrier metal. The barrier metal may be formed of materials such as a CVD-tungsten nitride (WN), a CVD-titanium nitride (Ti/TiN), or an ALD-tantalum nitride (TaN). The metal material may comprise tungsten (W) for example.

Conductive layer 8 may be further formed of a combination of materials such as polysilicon/tungsten or polysilicon/silicide. Examples of polysilicon/silicide include polysilicon/WSi, polysilicon/CoSi₂, and polysilicon/NiSi. A photoresist mask pattern is formed above the stack of tunnel oxide film 4, silicon film 6, charge trap film 7, IPD film 5, and conductive layer 8. The mask pattern is used as a mask to anisotropically etch the foregoing stack of films to form isolated gates MG (word lines WL) of memory-cell transistors Trm. Air gaps G are formed between the isolated gates MG as the result of the anisotropic etching.

At this stage of the manufacturing process flow, stacks of structures 4 to 8 remain above semiconductor substrate 1 located in the regions for forming embedded gates of select gates SGD1 and SGD2. The process steps such as those described above obtain the structures illustrated in FIG. 26A and FIG. 26B.

After forming the structures of gates MG (word lines WL) as described above, N-type impurities (such as arsenic (As)) are introduced between gates MG. The impurities are later activated by thermal treatment to serve as lightly-doped diffusion region 1a for each of memory-cell transistors Trm.

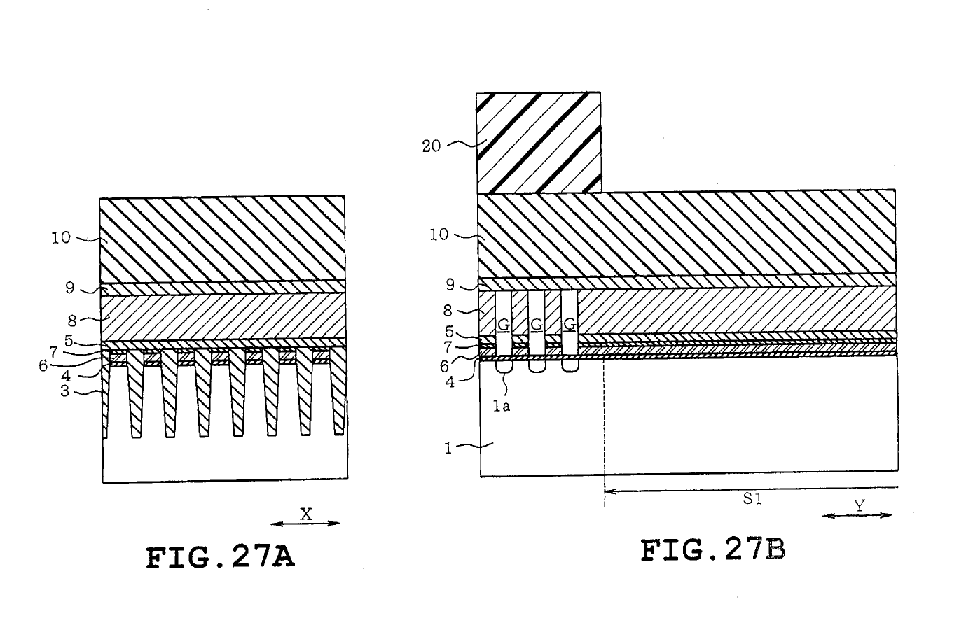

Then, as illustrated in FIGS. 27A and 27B, air gaps G are formed between gates MG by stacking insulating film 9. Insulating film 9 may be formed for example by plasma CVD. The gaps between gates MG (word lines WL) may be filled by insulating film 9 so as not to provide air gaps G.

Interlayer insulating film 10 is deposited above insulating film 9 by for example CVD. Interlayer insulating film 10 serves as a hard mask for removing the stack of structures 4 to 8 located in region S1 for forming select gate SGD1 or SGD2 and bit-line contact CB.

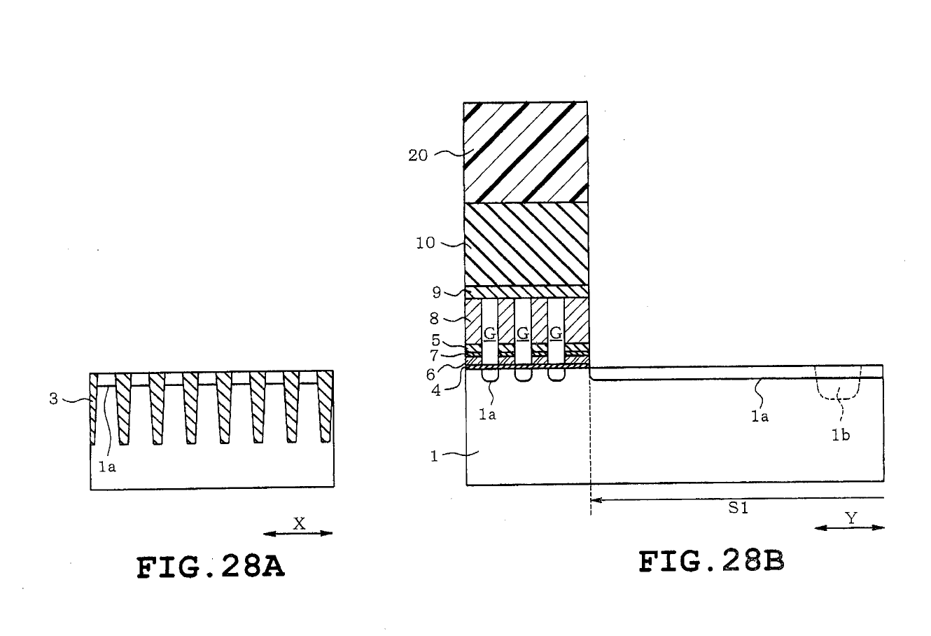

In order to remove the stack of structures 4 to 8 located in regions S1, resist 20 is formed and patterned to have an opening in regions S1. Then, as illustrated in FIG. 28A and FIG. 28B, stack of structures 4 to 10 above semiconductor substrate 1 located in regions S1 is completely removed by anisotropic etching. Resist 20 is thereafter removed by ashing or the like.

At this timing, N-type impurities for forming diffusion region 1a is introduced into the surface layer of semiconductor substrate 1 by ion implantation. It is also possible to form highly-doped diffusion layer region 1b at this timing. More specifically, a lithography process may be carried out to form an opening exposing only the region located below the portion where bit-line contact CB is to be formed and impurities may be introduced into such region.

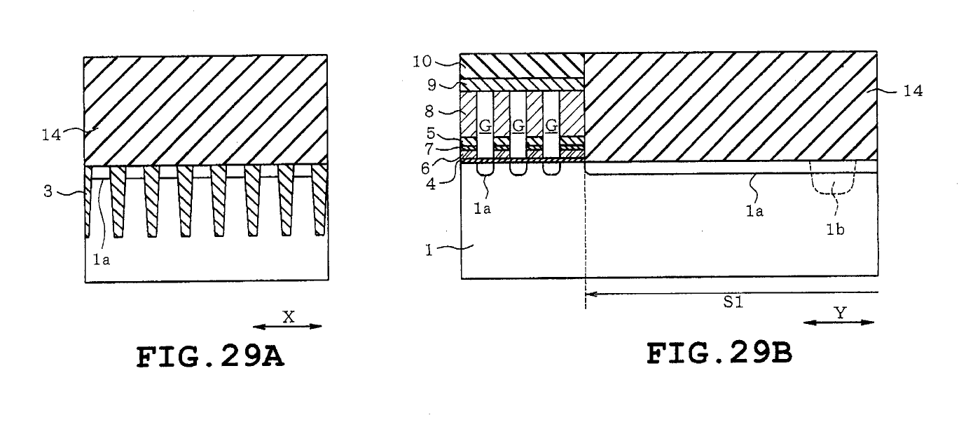

As illustrated in FIG. 29A and FIG. 29B, region S1 is filled with interlayer insulating film 14 (PMD: pre-metal dielectric) and the entire surface of interlayer insulating film 14 is etched back. As a result, it is possible to planarize the upper surface of interlayer insulating film 10 and the upper surface of interlayer insulating film 14.

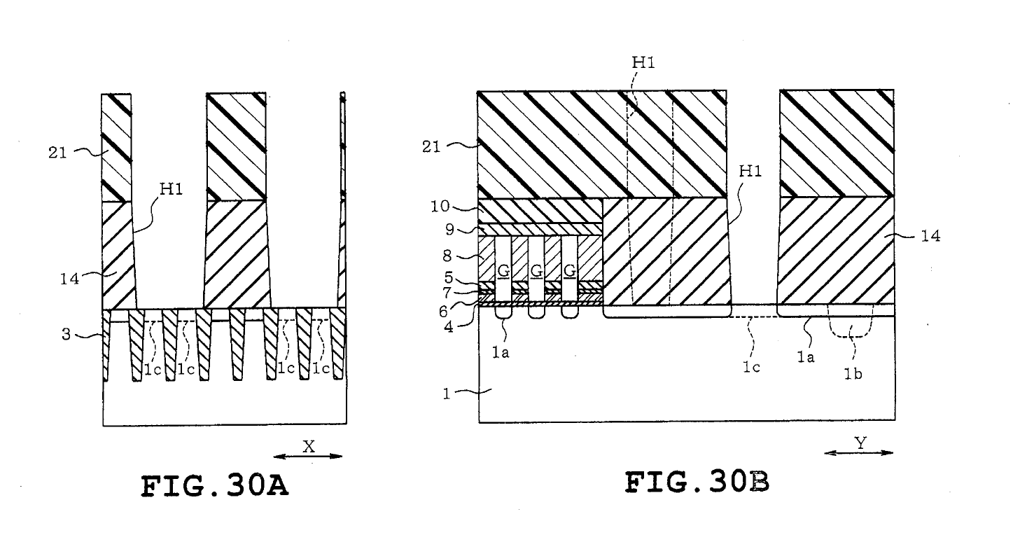

As illustrated in FIG. 30A and FIG. 30B, resist 21 is coated above the upper surface of interlayer insulating film 14. Then, resist 21 is patterned to form contact holes H1 for forming select gates SGD1 and SGD2. Contact holes H1 are arranged in a zigzag layout in plan view (See SGD1 and SGD2 in FIG. 24).

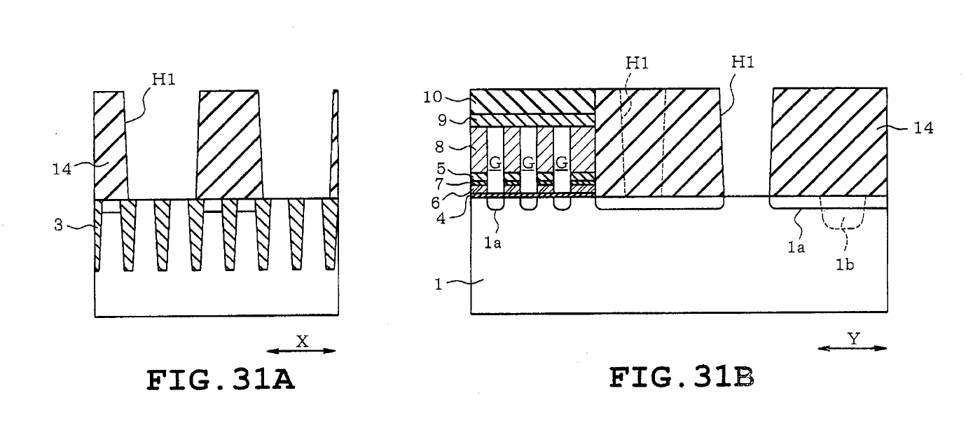

As illustrated in FIG. 30A and FIG. 30B, P-type impurities (such as boron (B)) are introduced by ion implantation in a self-aligned manner through contact hole H1 as indicated by ion implantation region 1c. As a result, it is possible to control the impurity concentration in channel region 1c of each of select transistors Trs1 and Trs2 which ultimately allows control of threshold voltages of select transistors Trs1 and Trs2. Referring now to FIG. 31A and FIG. 31B, resist 21 is removed.

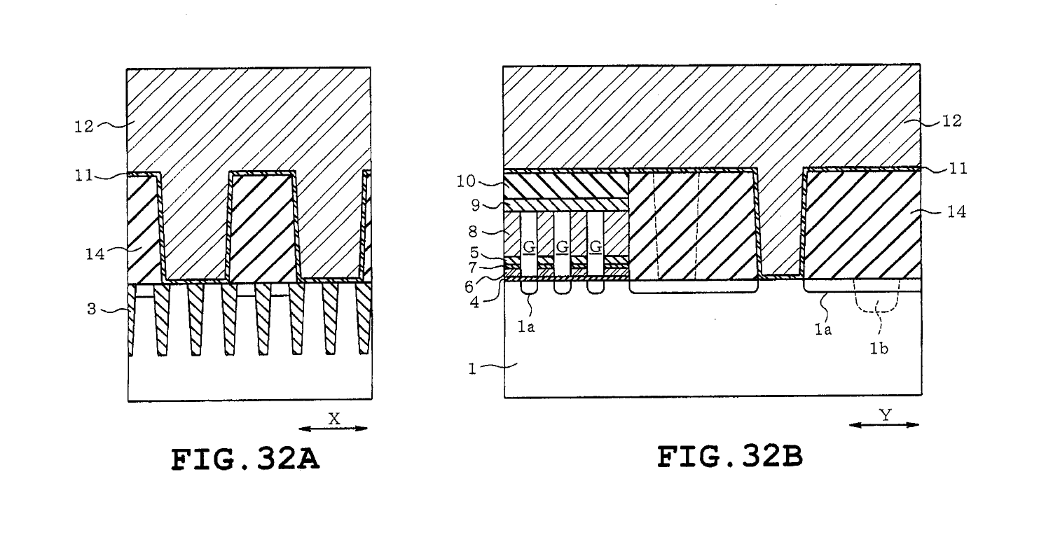

As illustrated in FIG. 32A and FIG. 32B, gate insulating film 11 comprising a silicon oxide film for example is formed above the upper surfaces of interlayer insulating films 10 and 14, along the inner surfaces of interlayer insulating film 14, and above the exposed upper surfaces of semiconductor substrate 1.

Gate insulating film 11 serves as a gate insulating film for select transistors Trs1 and Trs2. In one embodiment, gate insulating film 11 may be an HTO film formed by CVD for example. Then, conductive film 12 serving as a control electrode is filled above gate insulating film 11 by CVD for example. In one embodiment, conductive film 12 is formed of a polysilicon doped with impurities for example.

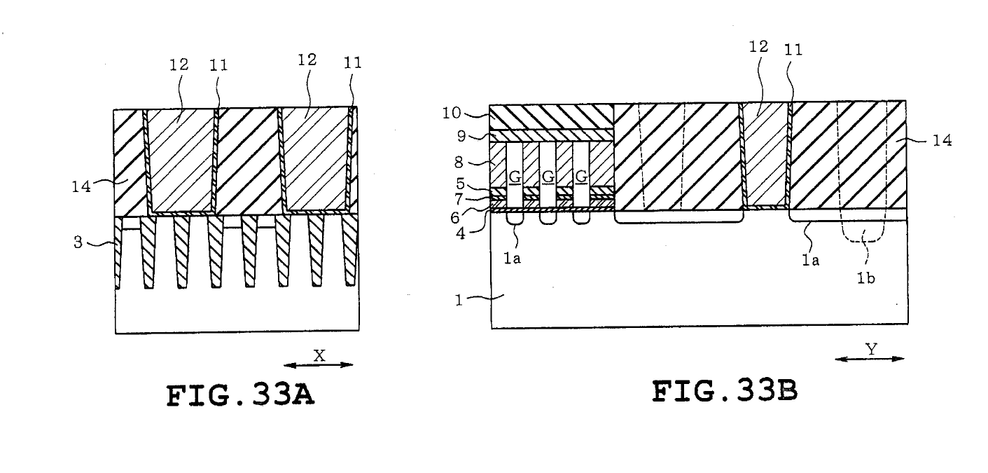

As illustrated in FIG. 33A and FIG. 33B, the entire surface of conductive film 12 is etched back until the upper surfaces of interlayer insulating films 10 and 14 are re-exposed. In an alternative embodiment, gate insulating film 11 may be configured to remain above the upper surfaces of interlayer insulating films 10 and 14 after the etch back of conductive film 12.

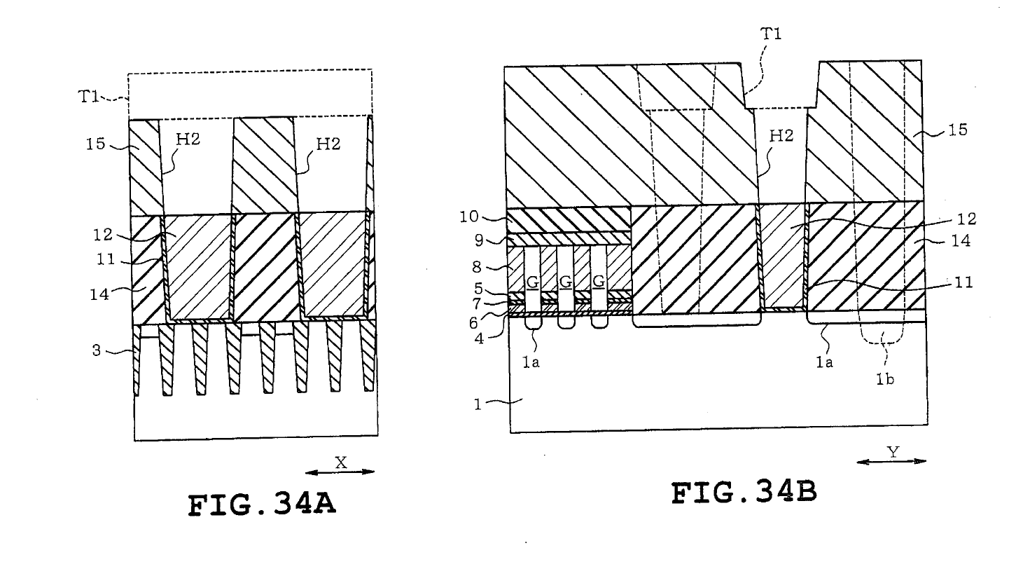

As illustrated in FIG. 34A and FIG. 34B, interlayer insulating film (PMD) 15 is deposited above interlayer insulating films 10 and 14 by CVD for example. Thereafter, a resist (not illustrated) is coated above interlayer insulating film 15 and patterned to form a mask which is used to form via holes H2.

Via hole H2 is formed so as to be aligned with contact hole H1 formed through interlayer insulating film 14. After stripping the resist, another resist pattern is formed for forming trench T1 extending in the X direction across each of via holes H2.

As illustrated in FIGS. 25A and 25B, via holes H2 and trenches T1 are filled with conductive films 13 and 16. In one embodiment, conductive films 13 and 16 may be formed of for example metal such as tungsten (W). For convenience of explanation, conductive films 13 and 16 are identified with different reference symbols; however, they are filled at the same time in the second embodiment.

As a result, via contacts formed of conductive film 13 and select gate lines SGL1 and SGL2 formed of conductive film 16 can be formed simultaneously. Contacts for connecting select gate lines SGL1 and SGL2 with upper layer wirings are formed in the subsequent process steps but will not be described as such steps are already known.

In the second embodiment, control circuit CC applies low-level voltage (≈0V) and power-supply voltage VD to select gate line SGL1 and select gate line SGL2, respectively when programming/reading each cell unit UC to enable the switching between the selected state/non-selected state. Thus, it is possible to achieve the effects similar to those of the first embodiment.

The second embodiment employs the so-called flat cell structure. Because silicon film 6 is formed extremely thin, it is difficult to stop the anisotropic etching within silicon film 6.

The use of wet etching instead of the anisotropic etching will necessitate an HF (hydrofluoric) chemical liquid for the removal of IPD film 5. When the extremely thin silicon film 6 is a polysilicon, the HF chemical liquid permeates into the grain boundaries of the polysilicon and results in the etching of tunnel insulating film 4. This may cause degradation of the gate breakdown voltage. Thus, it is difficult to form openings for select gates SGD1 and SGD2 even when wet etching is used.

In the manufacturing process flow of the third embodiment, it is no longer required to form an opening through IPD film 5 disposed above charge storing layer FG in the process of forming a structure similar to the gate MG of memory-cell transistor Trm during the formation of select gates SGD1 and SGD2.

### Third Embodiment

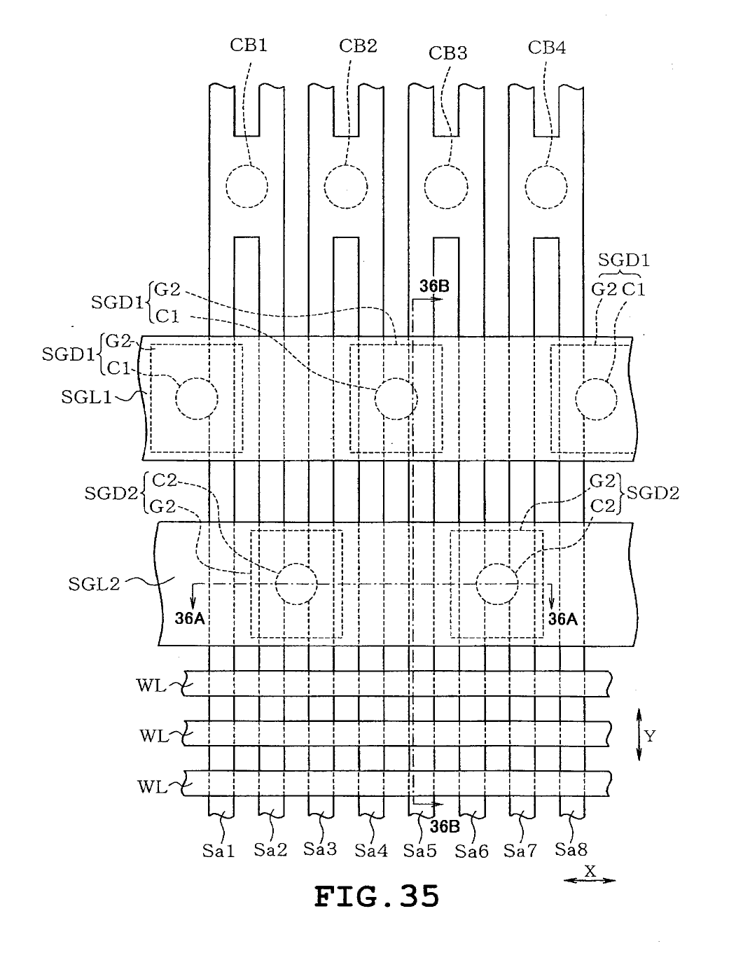

FIG. 35 to FIG. 44 illustrate a third embodiment. In the third embodiment, select gates SGD1 and SGD2 are disposed in a zigzag layout as was the case in the second embodiment. Further, bit lines BL are formed in a shared bit-line structure as was the case in the second embodiment.

In the third embodiment, select gates SGD1 and SGD2 are each formed as a stack structure substantially identical to the stack structure of the gate structure of memory-cell transistor Trm. The manufacturing process flow of select gates SGD1 and SGD2 will be described in the third embodiment. Select gate SGD3 may be formed in a similar structure by a similar manufacturing process flow.

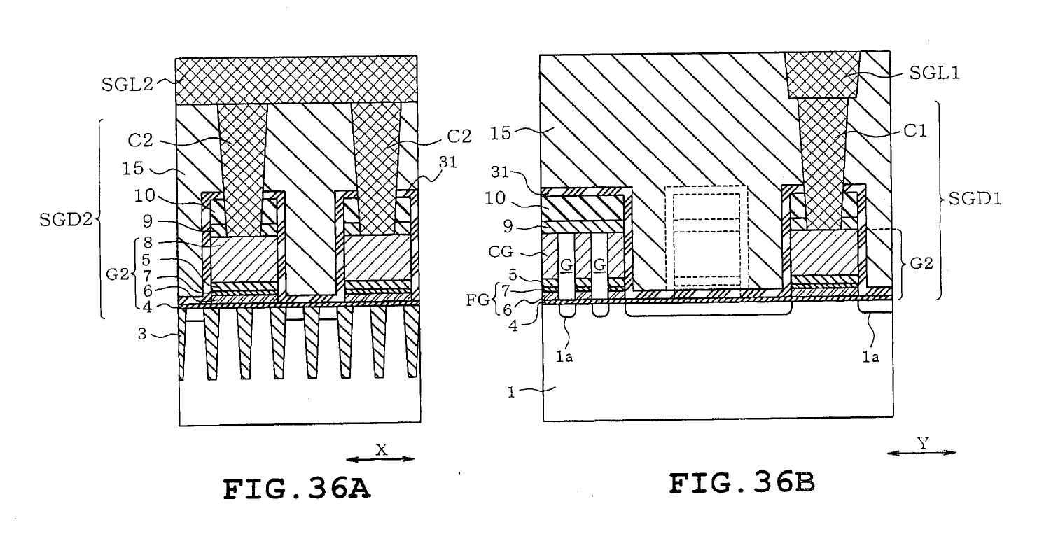

FIG. 35 is an enlarged plan view of the main portions illustrated in FIG. 24 and schematically illustrates embedded-type select gates SGD1 and SGD2, select gate lines SGL1 and SGL2, and bit line contacts CB of the third embodiment. FIG. 36B schematically illustrates the cross section taken along line 36B-36B of FIG. 35. FIG. 36A schematically illustrates the cross section taken along line 36A-36A of FIG. 35.

In the third embodiment, remainders of the stacks of structures 4 to 8 of memory-cell transistors Trm serve as the lower portions of select gates SGD1 and SGD2 as illustrated in FIG. 36A and FIG. 36B. In the following descriptions, the stack of structures 4 to 8 is referred to as stack structure G2.

Insulating films 9 and interlayer insulating films 10 are stacked above stack structures G2. Further, liner film 31 is formed along the sidewalls of stack structures G2, the sidewalls of insulating films 9 and interlayer insulating films 10, above the upper surfaces of interlayer insulating films 10, and above the upper surfaces of tunnel insulating film 4. Liner film 31 is configured for example as a stack of a silicon oxide film and a silicon nitride film. Holes are formed through insulating films 9, interlayer insulating films 10, and liner film 31 which are formed into gate contacts C1 and C2. Gate contact C1 is formed so as to contact stack structure G2 of select gate SGD1 and gate contact C2 is formed so as to contact stack structure G2 of select gate SGD2.

As illustrated in FIGS. 35 and 36A, conductive film 16 is formed so as to extend above multiple gate contacts C2 along the X direction to form select gate lines SGL2. Similarly, as illustrated in FIG. 35 and FIG. 36B, conductive film 16 is formed so as to extend above multiple gate contacts C1 along the X direction to form select gate lines SGL1.

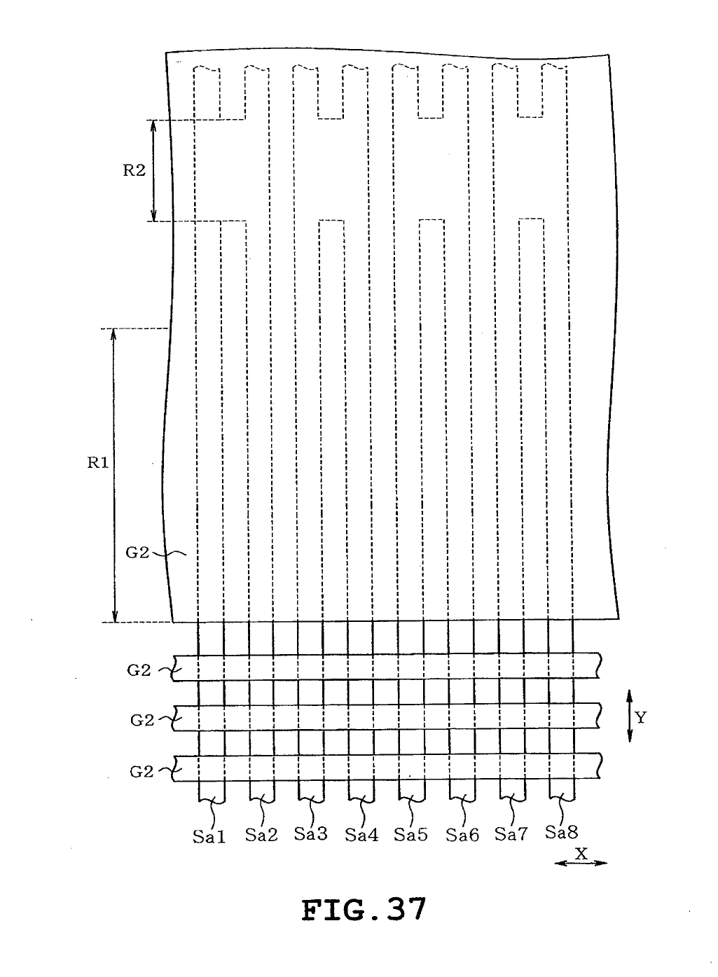

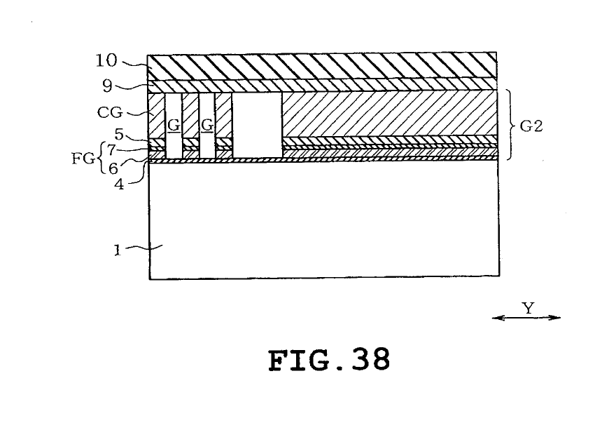

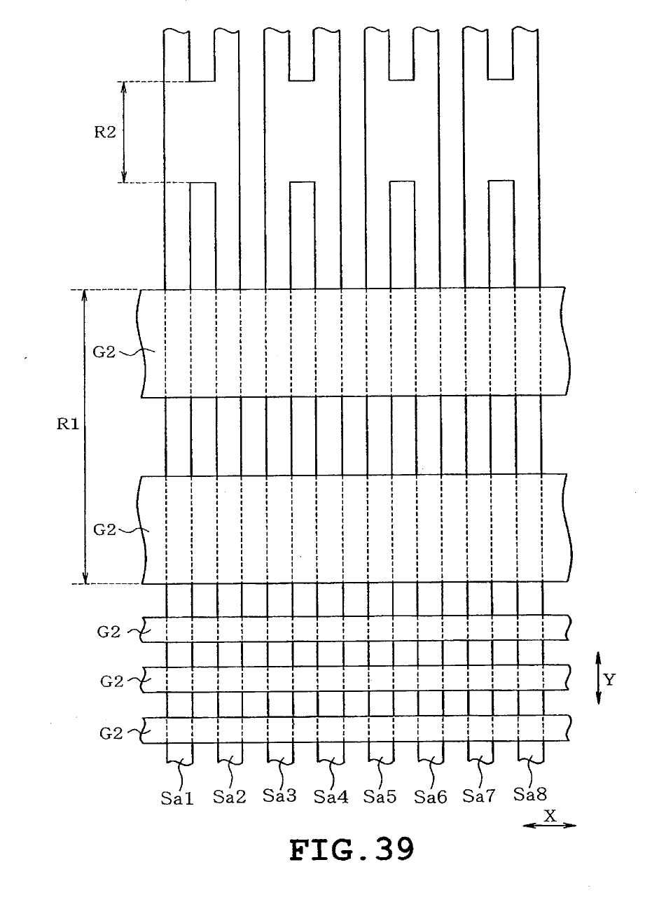

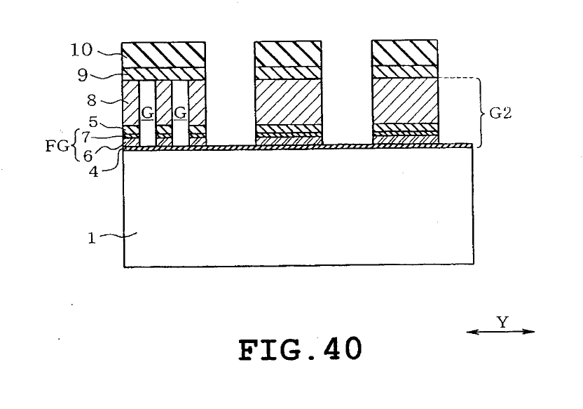

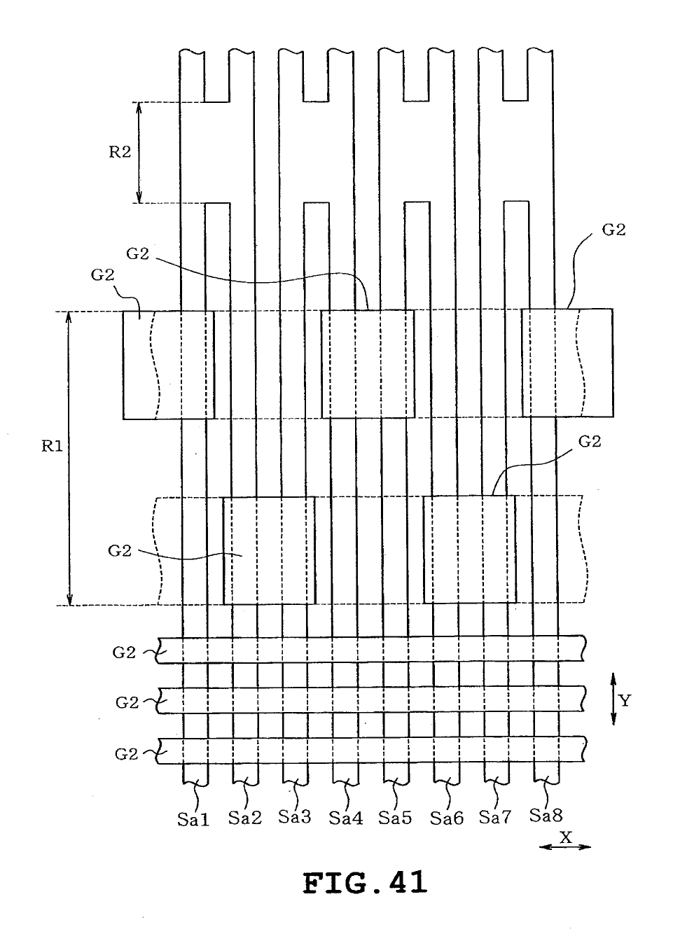

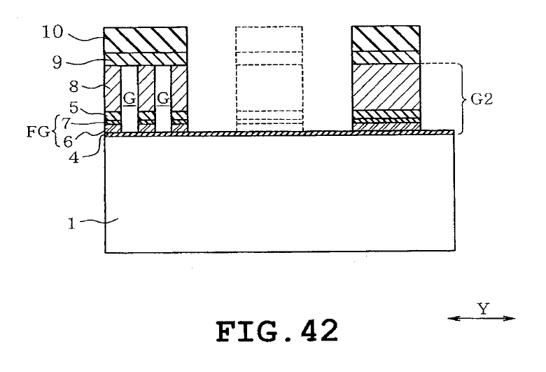

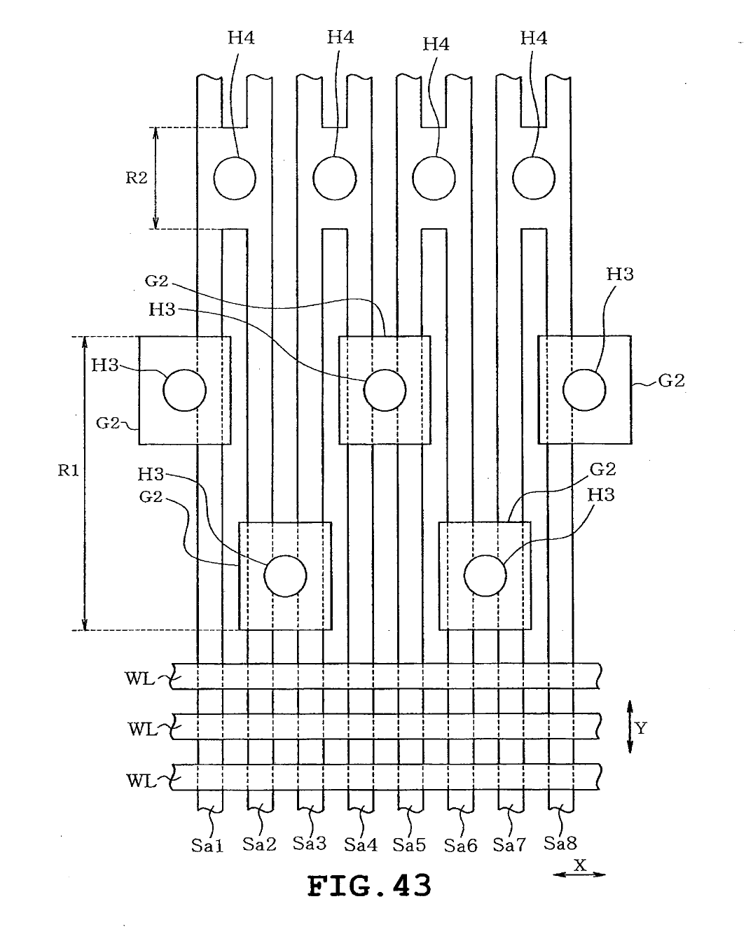

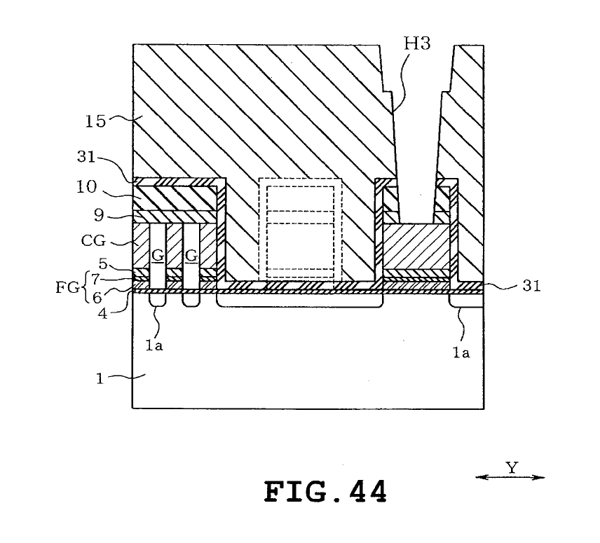

A description will be given on a manufacturing process flow of the third embodiment with reference to FIGS. 37 to 44. FIG. 37, FIG. 39, FIG. 41, and FIG. 43 are plan views each schematically illustrating one manufacturing phase of select gates SGD1 and SGD2 in the memory-cell region. FIG. 38, FIG. 40, FIG. 42, and FIG. 44 are examples of cross sections taken along line 36B-36B of FIG. 35 schematically illustrating the main portions at one phase of the manufacturing process flow illustrated in FIG. 37, FIG. 39, FIG. 41, and FIG. 43.

The following description will focus on the features of the third embodiment. However, process steps that are required for implementation or that are known may be further incorporated between the process steps discussed below. Further, the discussed process steps may be rearranged if practicable.

In the third embodiment, stack structures 4 to 8 (that is, stack structures G2) are formed above semiconductor substrate 1 by employing the process steps used in the second embodiment. FIG. 37 schematically illustrates element regions Sa (Sa1 to San) and regions serving as conductive layers 8 located on the upper surfaces of stack structures G2. FIG. 39 schematically illustrates the cross sections of the stack structures.

At this stage of the manufacturing process flow, the patterns for stack structures G2 remain in regions R1 for forming select gates SGD1 and SGD2 and in regions R2 for forming bit line contacts CB in addition to stack structures G2 for forming gates MG of memory-cell transistors Trm.

Then, as was the case in the process step illustrated in FIG. 27B, insulating film 9 is stacked to form air gaps G between each of gates MG. Then, interlayer insulating film 10 is formed above insulating film 9 by for example CVD.

Resist (not illustrated) having an opening in region S1 is patterned in order to remove the stack of structures 4 to 8 in region S1. Thereafter, a resist (not illustrated) is coated above interlayer insulating film 10. Then using the resist pattern as a mask, stack structure G2 within region R1 are divided in the Y direction as illustrated in FIGS. 39 and 40 by anisotropic etching. As a result, multiple strips of stack structures G2 (two in this example) extend in the X direction within region R1 so as to be divided in the Y direction. At this instance, stack structures G2 are removed from other regions including region R2.

As illustrated in FIGS. 41 and 42, stack structures G2 within region R1 are anisotropically etched. The anisotropic etching is performed so that stack structures G2 for select gates SGD1 within region R1 remain across adjacent element regions Sa4-Sa5, Sa8-Sa9, and so forth, respectively.

At the same time, stack structures G2 for select gates SGD2 within region R1 are anisotropically etched so as to remain across adjacent element regions Sa2-Sa3, Sa6-Sa7, and so forth. As a result, it is possible to dispose stack structures G2 in a zigzag layout as illustrated in FIG. 43.

As a result, stack structures G2 are allowed to remain within regions R1 as select gates SGD1 or SGD2, respectively. Then, impurities are introduced into the surface layer portion of semiconductor substrate 1 by ion implantation to form source/drain diffusion regions.

Then, liner film 31 is formed above the upper surfaces of insulating films 10, along the sidewalls of insulating films 10 and 9, along the sidewalls of stack structures G2, and above the upper surfaces of gate oxide film 4. Liner film 31 may be formed by stacking for example a silicon oxide film and a silicon nitride film by CVD. Insulating film 15 is further stacked above liner film 31 disposed above interlayer insulating film 10. Insulating film 15 is also filled between select gates SGD1 and between select gates SGD2. After planarizing insulating film 15 by CMP, via holes H3 for gate contacts C1 are formed in region R1 for forming select gates SGD1 and SGD2 as illustrated in FIGS. 43 and 44. At the same time, or before/after formation of via holes H3, contact holes H4 for bit-line contacts CB are formed in region R2 as illustrated in FIG. 43.

Then, via holes H3 and contact holes H4 are filled with gate contacts C1 and bit-line contacts CB, respectively. Thereafter, conductive film 16 is formed above gate contacts C1 and bit-line contacts CB to form bit lines BL.

In the third embodiment, a flat floating electrode structure is employed in which the thickness of charge storing layer FG is less than 10 nm. Thus, stack structure G2 is allowed to operate as select gate SGD1 or SGD2 without necessitating a process step for forming trenches.

As was the case in the foregoing embodiments, the third embodiment also allows selection of one appropriate cell unit UC among four adjacent cell units UC (UC1 to UC4, for example) through adjustment of potential applied to bit line BL and potential applied to select gate lines SGL1 and SGL2.

### Modified Embodiments

The first embodiment was described through an example in which two select transistors Trs1 and Trs 2 were formed in bit-line contact CB side. However, three or more select transistors may be formed in bit-line contact CB side instead.

The foregoing embodiments may be applied in programming two values, three values, or four or more values. That is, the foregoing embodiments described through a SLC (Single Level Cell) NAND flash memory application may be applied to an MLC (Multi Level Cell) application as well. The foregoing embodiments, described through examples in which memory-cell array Ar was configured by a single (region) plane, may be directed to a structure in which memory-cell array Ar is divided into multiple regions (planes).

One or more dummy transistors may be provided between select transistor Trs2 and memory-cell transistor Trm. Similarly, one or more dummy transistors may be provided between select transistor Trs3 and memory-cell transistor Trm.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a first memory-cell unit, a second memory-cell unit, a third memory-cell unit, and a fourth memory-cell unit each including:
a first select transistor,
a second select transistor series connected to the first select transistor,
a third select transistor, and
memory-cell transistors series connected between the first and the second select transistors and the third select transistor, each of the memory-cell transistors having a stack structure including a charge storing layer and a control electrode disposed above the charge storing layer via an insulating film,
wherein the first, the second, and the third select transistors each has a stack structure substantially identical to the stack structure of the memory-cell transistors;
a control circuit;
a first bit line connected to an end portion of the first select transistor in the first memory-cell unit and to an end portion of the first select transistor in the second memory-cell unit;
a second bit line connected to an end portion of the first select transistor in the third memory-cell unit and to an end portion of the first select transistor in the fourth memory-cell unit;
a first source line connected to an end portion of the third select transistor in the first memory-cell unit and to an end portion of the third select transistor in the fourth memory-cell unit; and
a second source line connected to an end portion of the third select transistor in the second memory-cell unit and to an end portion of the third select transistor in the third memory-cell unit;
threshold voltages of the first select transistors in the first and the fourth memory-cell unit and the second transistors in the second and third memory-cell unit differ from the threshold voltages of the second select transistors in the first and the fourth memory-cell unit and the first select transistors in the second and third memory-cell unit.

2. The nonvolatile semiconductor storage device according to claim 1, wherein the memory-cell transistors are series connected in a first direction and the first, the second, the third, and the fourth memory-cell unit are disposed adjacently in a second direction crossing the first direction, and
further comprising first source-line contacts being disposed with spacing in the second direction, the first source-line contacts being disposed at the end portion of the third select transistor in the first memory-cell unit and at the end portion of the third select transistor in the fourth memory-cell unit, respectively, and
wherein the first source line extends above and across the first source-line contacts and comprises a first wiring structure extending substantially in a straight line in the second direction, and
further comprising second source-line contacts being disposed with spacing in the second direction, the second source-line contacts being disposed at the end portion of the third select transistor in the second memory-cell unit and at the end portion of the third select transistor in the third memory-cell unit, respectively, and
wherein the second source line extends above and across the second source-line contacts and comprises a second wiring structure extending substantially in a straight line in the second direction.

3. The nonvolatile semiconductor storage device according to claim 2, wherein the third select transistor in the first, the second, the third, and the fourth memory-cell unit further includes a select gate, and
wherein the first source-line contacts are spaced in the first direction by a first distance from the select gates of the third select transistors in the first and the fourth memory-cell unit, respectively, and
wherein the second source-line contacts are spaced in the first direction by a second distance different from the first distance from the select gates of the third select transistors in the second and the third memory-cell unit, respectively.

4. The nonvolatile semiconductor storage device according to claim 1, wherein the memory-cell transistors are series connected in a first direction, the first, the second, the third, and the fourth memory-cell unit are disposed adjacently in a second direction crossing the first direction, and
further comprising a first bit-line contact being connected to the first bit line and being disposed at the end portion of the first select transistor in the first memory-cell unit and at the end portion of the first select transistor in the second memory-cell unit, and
further comprising a second bit-line contact being connected to the second bit line and being disposed at the end portion of the first select transistor in the third memory-cell unit and at the end portion of the first select transistor in the fourth memory-cell unit.

5. The nonvolatile semiconductor storage device according to claim 4, wherein the first select transistor in the first, the second, third, and fourth memory-cell unit further includes a select gate, and
wherein the first bit-line contact is spaced in the first direction by a third distance from the select gates of the first select transistors in the first and the second memory-cell unit, and
wherein the second bit-line contact is spaced in the first direction by a fourth distance different from the third distance from the select gates of the first select transistors in the third and the fourth memory-cell unit.

6. The nonvolatile semiconductor storage device according to claim 1, wherein threshold voltages of the first select transistors in the first and fourth memory-cell unit and threshold voltages of the second select transistors in the second and the third memory-cell unit fall within a first threshold voltage distribution, and
wherein threshold voltages of the second select transistors in the first and the fourth memory-cell unit and threshold voltages of the first select transistors in the second and the third memory-cell unit fall within a second threshold voltage distribution having an upper limit threshold voltage less than a lower limit threshold voltage of the first threshold voltage distribution.

7. The nonvolatile semiconductor storage device according to claim 6, wherein the upper limit threshold voltage of the second threshold voltage distribution is less than zero and the lower limit threshold voltage of the first threshold voltage distribution is greater than zero.

8. The nonvolatile semiconductor storage device according to claim 1, wherein the control circuit is configured to, when specifying threshold voltages of the first select transistors in the second and the third memory-cell unit, allow execution of a first pre-process in which the threshold voltages of the first select transistors in the second and third memory-cell unit are modified by:
applying a first voltage to the second source line,
applying a second voltage greater than the first voltage to the first source line,
rendering the second and the third select transistors and the memory-cell transistors in a conductive state, and
applying a programming voltage to the control electrodes of the first select transistors, and
wherein the control circuit is configured to, when specifying threshold voltages of the second select transistors in the first and the fourth memory-cell unit, allow execution of a second pre-process in which the threshold voltages of the second select transistors in the first and fourth memory-cell unit are modified by:
applying a third voltage to the first source line,
applying a fourth voltage greater than the third voltage to the second source line,
rendering the second and the third select transistors and the memory-cell transistors in a conductive state, and
applying a programming voltage to the control electrodes of the second select transistors.

9. The nonvolatile semiconductor storage device according to claim 1, further comprising word lines connecting the memory-cell transistors,
wherein the control circuit is configured to, when writing data into the memory-cell transistors, allow application of a programming voltage to the control electrodes of the memory-cell transistors targeted for programming through the word lines connected to the memory-cell transistors targeted for programming by:
rendering the first and the second select transistors in a memory-cell unit selected for programming in a conductive state,
turning off the third select transistor in the memory-cell unit selected for programming,
turning off at least either of the first or second select transistors in a memory-cell unit not selected for programming, and
turning off the third select transistors in the memory-cell unit not selected for programming.

10. A nonvolatile semiconductor storage device comprising:
a first memory-cell unit, a second memory-cell unit, a third memory-cell unit, and a fourth memory-cell unit each including:
an element region,
a first select transistor formed above the element region,
a second select transistor formed above the element region and series connected to the first select transistor,
a third select transistor formed above the element region, and
memory-cell transistors series connected in a first direction between the first and the second select transistors and the third select transistor, the first, the second, the third, and the fourth memory-cell unit being disposed adjacently in a second direction crossing the first direction;
a first bit line connected to an end portion of the first memory-cell unit and to an end portion in the second memory-cell unit;
a second bit line connected to an end portion of the third memory-cell unit and to an end portion in the fourth memory-cell unit;
a first select gate formed of a single electrode disposed above the element region in the first memory-cell unit and above the element region in the fourth memory-cell unit via a gate insulating film;
a first select gate line connected to the first select gate disposed above the element region in the first memory-cell unit and to the first select gate disposed above the element region in the fourth memory-cell unit, and extending above and across the element region in the second memory-cell unit and the element region in the third memory-cell unit;
a second select gate formed of a single electrode disposed above the element region in the second memory-cell unit and above the third memory-cell unit via a gate insulating film; and
a second select gate line connected to the second select gate disposed above the element region in the second memory-cell unit and to the second select gate disposed above the element region in the third memory-cell unit, and extending above and across the element region in the first memory-cell unit and the element region in the fourth memory-cell unit.

11. The nonvolatile semiconductor storage device according to claim 10, further comprising a first conductive film disposed above the first select gate and extending substantially in a straight line in the second direction, and a second conductive film disposed above the second select gate and extending substantially in a straight line in the second direction.

12. The nonvolatile semiconductor storage device according to claim 10, wherein the first and the second bit line are disposed at a pitch width twice a width of the element region taken along the second direction.

13. The nonvolatile semiconductor storage device according to claim 10, wherein each of the memory-cell transistors is provided with a gate stack structure including a charge storing layer and a control electrode disposed above the charge storing layer via an insulating film, and wherein the first select gate and the second select gate are each provided with a gate structure being different from the gate stack structure of the memory-cell transistors.

14. The nonvolatile semiconductor storage device according to claim 10, wherein the memory-cell transistors is provided with a gate stack structure including a charge storing layer and a control electrode disposed above the charge storing layer via an insulating film, and wherein the first select gate and the second select gate are each provided with a gate structure being substantially identical to the gate stack structure of the memory-cell transistors.
